(19) United States
(12) Patent Application Publication
(10) Pub. No.: US 2025/0112205 A1
(43) Pub. Date: Apr. 3, 2025

(54) DIE-TO-DIE INPUT/OUTPUT SIGNAL ROUTING UTILIZING OPPOSING DIE SURFACES IN INTEGRATED CIRCUIT COMPONENT PACKAGING

(71) Applicant: Intel Corporation, Santa Clara, CA (US)

(72) Inventors: Prashant Majhi, San Jose, CA (US); Nitin A. Deshpande, Chandler, AZ (US); Omkar G. Karhade, Chandler, AZ (US); Surhud V. Khare, Buffalo, NY (US)

(73) Assignee: Intel Corporation, Santa Clara, CA (US)

(21) Appl. No.: 18/478,950

(22) Filed: Sep. 29, 2023

(51) Int. Cl. H01L 25/065; H01L 21/56; H01L 23/00; H01L 23/538; H01L 25/00

(52) U.S. Cl. CPC H01L 25/0652; H01L 21/568; H01L 23/5389; H01L 24/08; H01L 24/24; H01L 24/82; H01L 25/50; H01L 2224/08145; H01L 2224/24137; H01L 2224/245; H01L 2224/82005; H01L 2924/01013; H01L 2924/01029; H01L 2924/01073; H01L 2924/01074; H01L 2924/04953

(57) ABSTRACT

Input/output (I/O) routing from one integrated circuit die to other integrated circuit dies in an integrated circuit component comprising heterogeneous and vertically stacked die is made from the top and bottom surfaces of the integrated circuit die to the other dies. Die-to-die I/O routing from the die to laterally adjacent die is made from the top surface of the die via one or more redistribution layers. Die-to-die routing from the die to vertically adjacent die is made via hybrid bonding on the bottom surface of the die. Embedded bridges or chiplets or not used for die-to-die I/O routing, which can free up space for more through-dielectric vias to provide power and ground connections to the die, which can provide for improved power delivery.

### BACKGROUND

Integrated circuit components can comprise heterogeneous integrated circuit dies-dies of different types (processors, memories, etc.), designs, sizes, and fabricated with differing processing nodes. The die-to-die routing of input/output signals between integrated circuit dies and the routing of power signals to integrated circuit dies in an integrated circuit component can comprise redistribution layers, embedded bridges or chiplets, and through-dielectric vias.

### BRIEF DESCRIPTION OF THE DRAWINGS

FIG. 1 is a cross-sectional view of a microelectronics structure employing an embedded bridge for routing between dies.

FIG. 2A is a cross-sectional view of an example microelectronic structure comprising two integrated circuit dies attached to a carrier wafer.

FIG. 2B is a cross-sectional view of the example microelectronic structure of FIG. 2A after removal of the substrate regions of the integrated circuit dies.

FIG. 2C is a cross-sectional view of the example microelectronic structure of FIG. 2B after formation of a liner layer and a dielectric layer on the structure.

FIG. 2D a cross-sectional view of the example microelectronic structure of FIG. 2C after thinning of the dielectric layer and planarization of the resulting top surface of the structure.

FIG. 2E is a cross-sectional view of the example microelectronic structure of FIG. 2D after formation of a redistribution layer region and through-dielectric vias.

FIG. 2F is a cross-sectional view of the example microelectronic structure of FIG. 2E after attachment of a thermo-mechanical substrate to the structure.

FIG. 2G is a cross-sectional view of the example structure of FIG. 2F after removal of the carrier wafer and bonding layer attachment of a structure comprising integrated circuit dies.

FIG. 3 is an example method of forming a structure comprising die-to-die routing utilizing opposing surfaces of an integrated circuit die.

FIG. 4 is a top view of a wafer and dies that may be included in a microelectronic assembly, in accordance with any of the embodiments disclosed herein.

FIG. 5 is a cross-sectional side view of an integrated circuit device that may be included in a microelectronic assembly, in accordance with any of the embodiments disclosed herein.

FIGS. 6A-6D are perspective views of example planar, FinFET, gate-all-around, and stacked gate-all-around transistors.

FIGS. 7A and 7B are perspective and cross-sectional views of example forksheet gate-all-around transistors.

FIGS. 8A and 8B are perspective and cross-sectional views of an example complementary field-effect-transistor (CFET) architecture.

FIG. 9 is a cross-sectional side view of an integrated circuit device assembly that may include a microelectronic assembly, in accordance with any of the embodiments disclosed herein.

FIG. 10 is a block diagram of an example electrical device that may include a microelectronic assembly, in accordance with any of the embodiments disclosed herein.

### DETAILED DESCRIPTION

The number of cores and caches integrated into integrated circuit components continues to scale in succeeding semiconductor manufacturing technology generations. Design factors, such as increasing cache-to-core ratios, are also contributing to the increase in the number of caches in an integrated circuit component. To mitigate the impact that integrating more cores and caches onto a single die would have on yield, core and cache functionality is being disaggregated into smaller separate dies or chiplets. Further driving disaggregation is that different process nodes may be desired for cost, performance, or other reasons for the different components (e.g., cores, caches, fabric) in an integrated circuit component. The vertical stacking of chiplets in an integrated circuit component (which is commonly referred as “3D Packaging”) is one approach to reduce the impact of routing I/O signals between dies on performance. As the level of disaggregation increases, the complexity of routing I/O signals between dies increases to satisfy performance demands. As the complexity of I/O signal routing between dies increases, the number of interconnect routing layers used to implement the die-to-die routing can also increase.

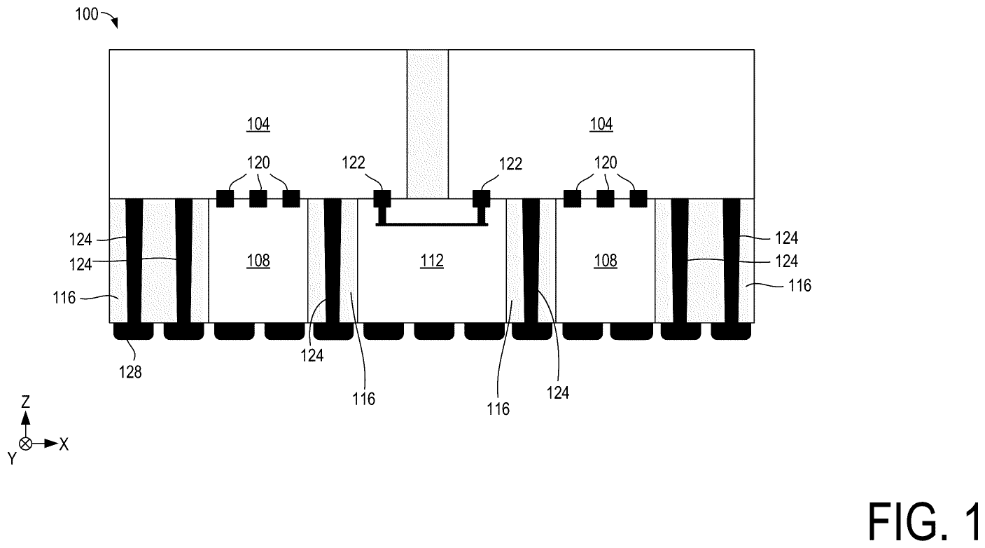

FIG. 1 is a cross-sectional view of a microelectronics structure employing an embedded bridge for routing between dies. The structure 100 comprises two core dies 104 that implement core and fabric functionality and two cache dies 108 that implement last-level cache functionality. Connections 122 between the integrated circuit die 104 and the embedded bridge 112 allow the embedded bridge 112 to provide the routing for I/O signals between the integrated circuit dies 104. The embedded bridge 112 is embedded in a dielectric layer 116 and can comprise a substrate comprising metal lines and vias that form conductive paths through the bridge. The embedded bridge 112 can be an active embedded bridge that comprises transistors or other active devices or a passive embedded bridge that does not comprise active components. The embedded bridge 112 can be fully embedded in the dielectric layer 116, with the dielectric layer 116 surrounding the embedded bridge 112 or partially embedded, with at least a surface of the embedded bridge 112 not covered by the dielectric layer 116. Die-to-die routing between the core dies 104 and the cache dies 108 is via connection of bond pads on the bottom surfaces of the cores dies 104 to bond pads on the top surfaces of the cache dies 108 (illustrated via connection 120). Through-dielectric vias (TDVs) 124 provide power signals to the core dies 104. Conductive contacts 128, which may be bumps, microbumps, or pillars, can connect the structure 100 to a package substrate of an integrated circuit component.

The presence of the embedded bridge 112, while enabling die-to-die routing between the core dies 104, prevents additional TDVs from being used to route power to the core dies 104. This can result in less robust power delivery as each of the TDVs 124 may experience a larger voltage drop than each of a larger number of TDVs delivering the same amount of overall current to the core dies 104. The embedded bridge 112 can also introduce process complexities as the embedded bridge 112 and the cache dies 108 can be heterogeneous dies. For example, the embedded bridge 112 and the cache dies 108 may be part of a reconstituted wafer that is attached to the core dies 104 to form the structure 100. The process flow for forming a reconstituted wafer comprising an embedded bridge 112 that may be much thinner than the cache dies 108 can be more complicated than forming a reconstituted wafer comprising just cache dies 108. Differing bond pad sizes and densities between the embedded bridge 112 and the cache dies 108 to which the core dies 104 connect can create additional process complexities. These additional processing complexities can result in higher yield loss relative to processing flows where cores dies 104 are attached to homogeneous chiplets.

Existing approaches to overcome these disadvantages of using embedded bridges to enable die-to-die routing include exploring ways to increase TDV counts in the areas not occupied by the embedded bridges to improve power routing to the dies for which the embedded bridge is providing I/O routing and to improve the yield of processing flows that integrate heterogeneous embedded bridges and chiplets in the same layer that are to be bonded to the same dies. However, increasing TDV counts may not be feasible as the real estate available for TDVs in the presence of embedded bridges may be limited, and process development to accommodate heterogenous embedded bridges and dies in the same layer consumes time and money and can result in more complex and more costly process flows. Additional challenges presented by the use of embedded bridges are that embedded bridges can have highly skewed aspect ratios (the thickness of embedded bridges can be much less than their width and depth) and can have dimensions less than 2 millimeters. These embedded bridge aspect ratios and dimensions can provide challenges for embedded bridge handling and integrated circuit component assembly. Further, in integrated circuit component designs comprising a large number of embedded bridges (which can result from a high level of disaggregation), the large number of chiplets and embedded bridges that need to be assembled and handled can impact assembly yield.

Disclosed herein are technologies for enabling die-to-die I/O routing that utilize opposing surfaces of an integrated circuit die for the die-to-die I/O routing. The integrated circuit die comprises a transistor region positioned between two metallization stacks. Die-to-die I/O routing between an integrated circuit die to a laterally adjacent integrated circuit die utilizes conductive contacts on a first surface of the integrated circuit die along with metal lines in a redistribution layer region positioned above the integrated circuit die and die-to-die routing between the integrated circuit die and a vertically adjacent die utilizes conductive contacts on a second surface of the integrated circuit die that is opposite to the first surface. The die-to-die routing technologies disclosed herein do not rely on embedded bridges or chiplets. The absence of embedded bridges frees up real estate that can be used to incorporate a greater number of TDVs for power supply routing, which can result in more robust power delivery to integrated circuit dies.

The technologies described herein have at least the following advantages. First, they can enable improved power delivery to integrated circuit dies due to lower voltage drop collectively across a greater number of through-dielectric vias. Second, they can enable lower processing costs (due to a simpler processing flow and improved yield) by not having to integrate embedded bridges into the same layer as other dies to create a structure comprising a layer of heterogeneous integrated circuit dies. Third, the disclosed technologies can support both redistribution layer and far back-end metal integration into a process flow as the wafer-level assembly process is similar to the on-die far back-end metal fabrication. Fourth, the number of metal layers in the redistribution layer region and the density of metal lines (e.g., wires/mm) in individual metal layers in a redistribution layer region can be readily scaled as the complexity of die-to-die connections between laterally spaced integrated circuit dies increases.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or in any other manner. “Connected” may indicate elements are in direct physical or electrical contact with each other and “coupled” may indicate elements co-operate or interact with each other, but they may or may not be in direct physical or electrical contact. Furthermore, the terms “comprising,” “including,” “having,” and the like, as used with respect to embodiments of the present disclosure, are synonymous.

Terms modified by the word “substantially” include arrangements, orientations, spacings, or positions that vary slightly from the meaning of the unmodified term. For example, the portion of a first layer or feature that is substantially perpendicular to a second layer or feature can include a first layer or feature that is +/−20 degrees from a second layer or feature, a first surface that is substantially parallel to a second surface can include a first surface that is within several degrees of parallel from the second surface, and a layer that is substantially planar can include layers that comprise some dishing, bumps, or other non-planar features resulting from processing variations and/or limitations. Further, a first layer that is substantially coplanar with another second layer includes first layers that are offset by a small amount due to processing variations and limitations. Moreover, a stated value for a dimension, feature, or characteristic qualified by the term “about” (e.g., thickness, distance) includes values within +/−10% of the stated value. Similarly, a stated range of values for a dimension, feature, or characteristic includes values within 10% of the listed upper and lower values for the range.

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components. Conductive contacts located on a surface can be flush with the surface or comprise a portion of the conductive contact that extends past the surface.

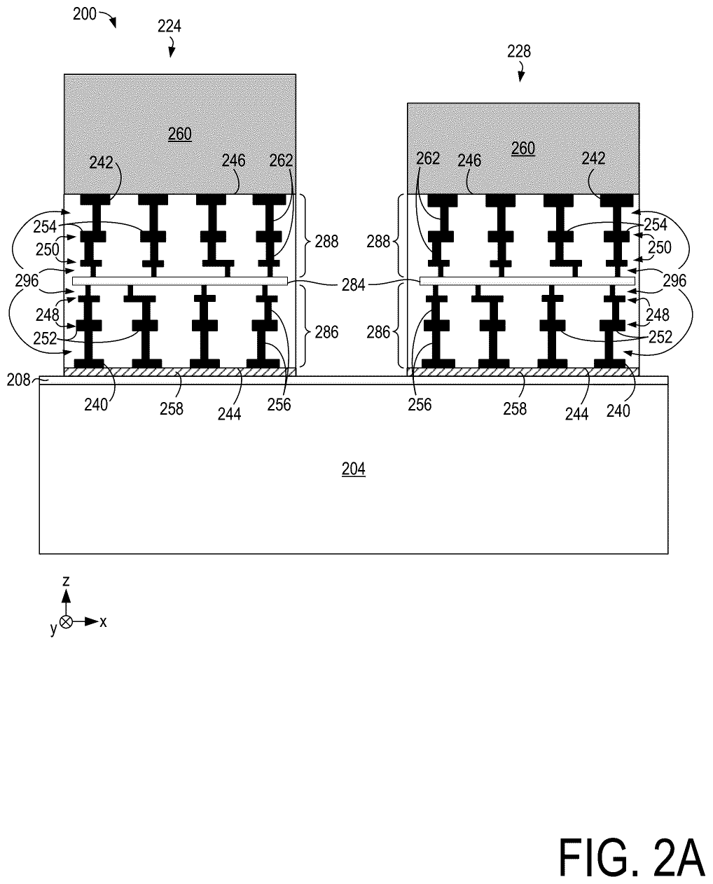

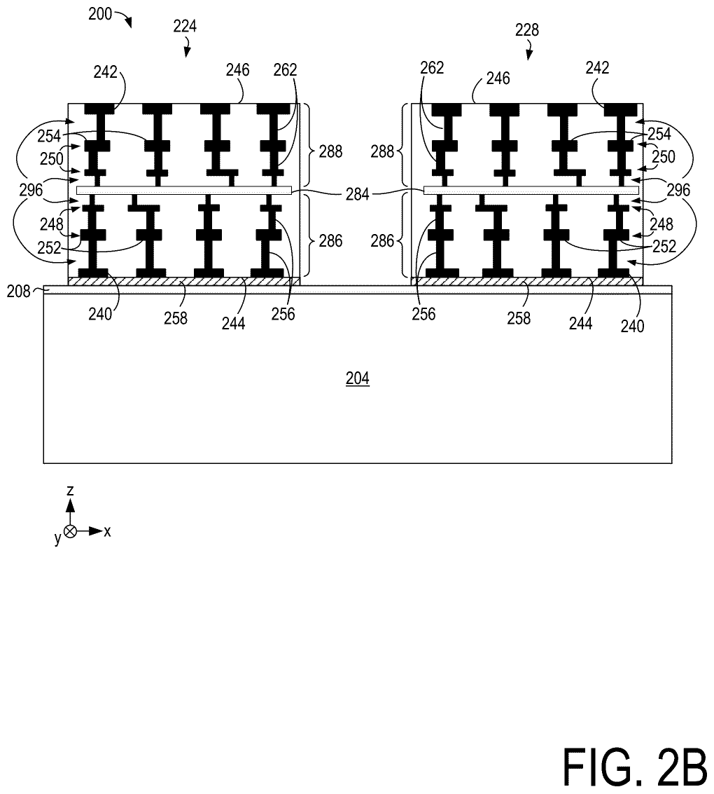

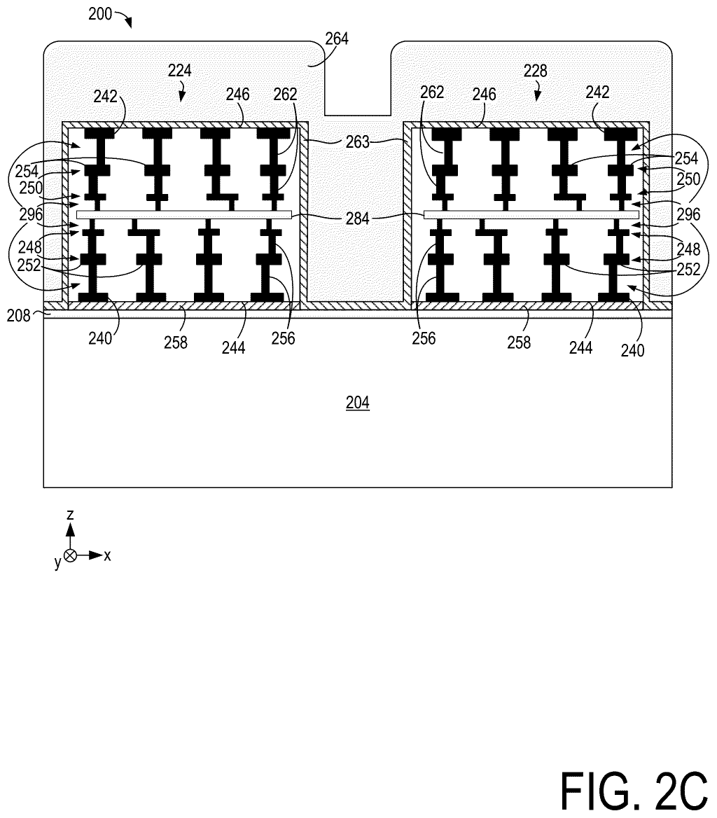

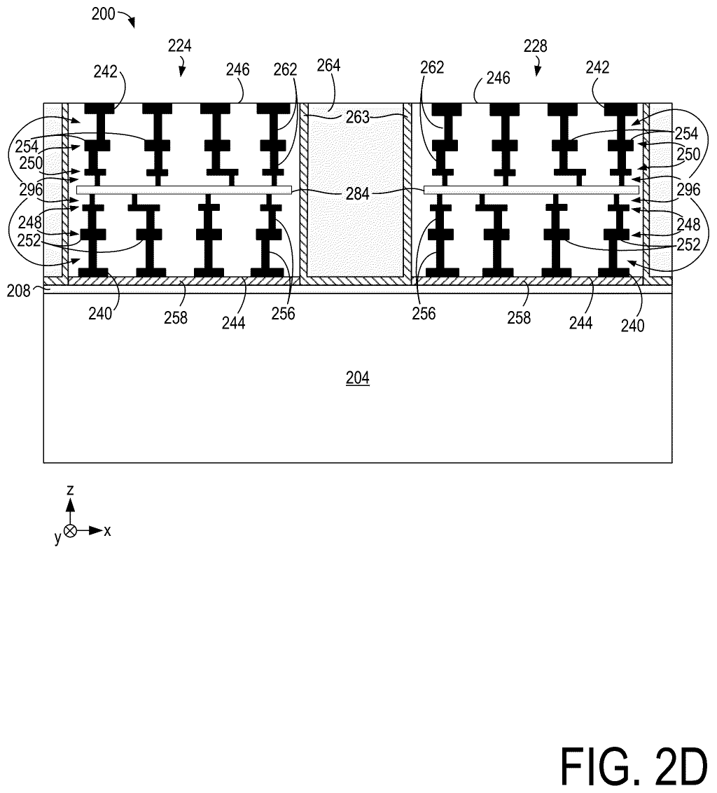

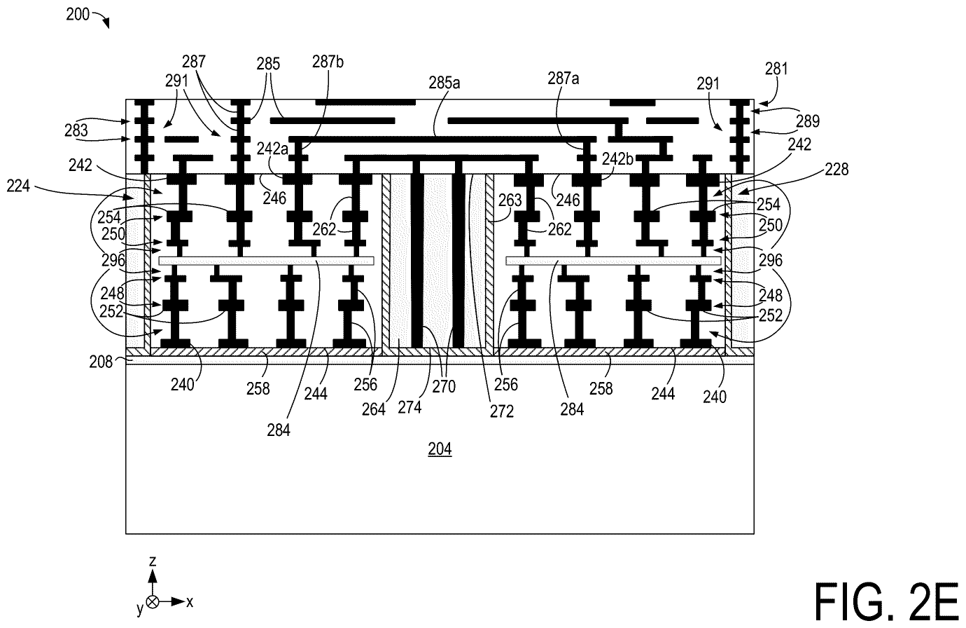

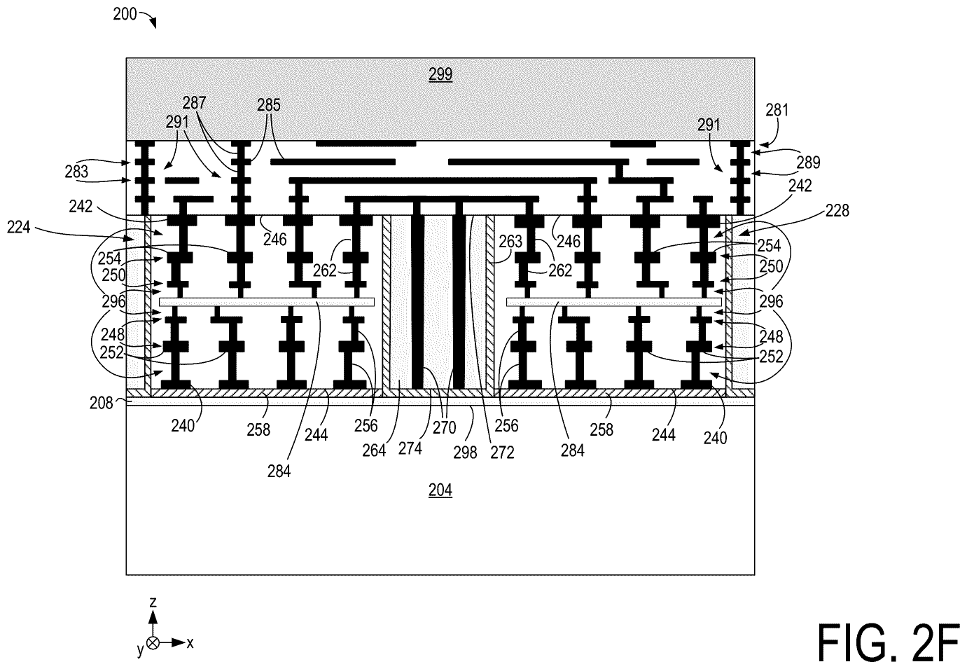

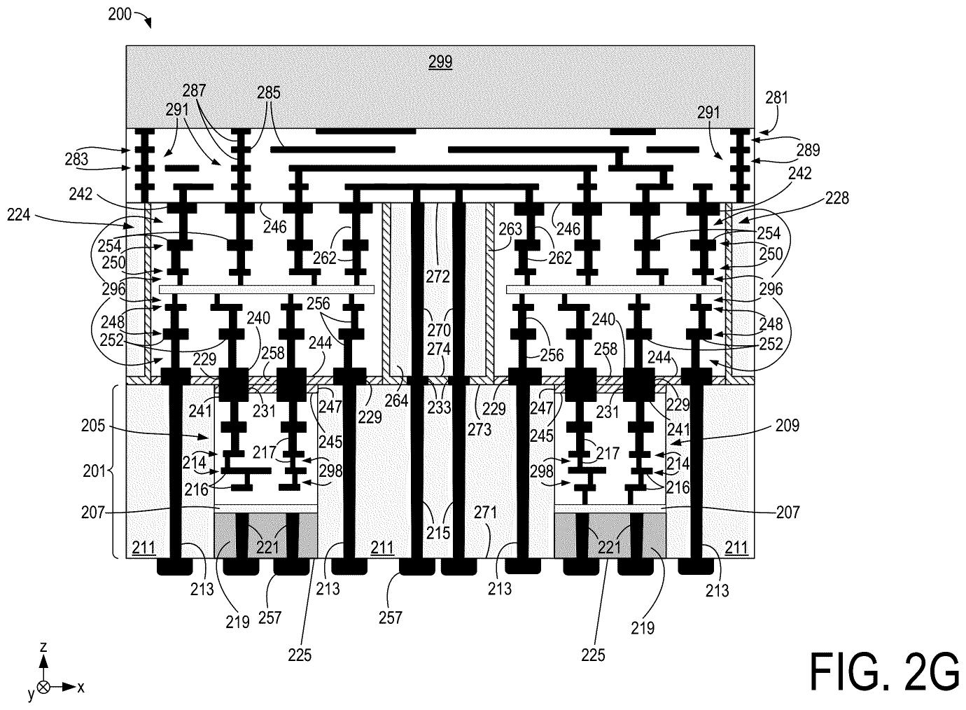

As used herein, the term “attached” in the context of a feature or component attached to a conductive contact includes connections between the feature or component and the conductive contact where there is a via extending through one or more die bonding layers between the feature and the feature or component. For example, with reference to FIG. 2G, a conductive contact 241 on integrated circuit die 205 is attached to a conductive contact 240 in integrated circuit die 224 by a via 231 extending through die bonding layers 247 and 258.

As used herein, the term “adjacent” refers to layers or components that are in physical contact with each other. That is, there is no layer or component between the stated adjacent layers or components. For example, a layer X that is adjacent to a layer Y refers to a layer that is in physical contact with layer Y.

As used herein, the phrase “positioned between” in the context of a first layer or component positioned between a second layer or component and a third layer or component refers to the first layer or component being directly physically attached to the second and/or third parts or components (no layers or components between the first and second layers or components or the first and third layers or components) or physically attached to the second and/or third layers or components via one or more intervening layers or components. For example, with reference to FIG. 2A, the transistor regions 284 are positioned between the first metallization regions 286 and the second metallization regions 288.

Certain terminology may also be used herein for the purpose of reference only, and thus are not intended to be limiting. For example, terms such as “upper,” “lower,” “above,” “below,” “bottom,” and “top” refer to directions in the Figures to which reference is made. Terms such as “front,” “back,” “rear,” and “side” describe the orientation and/or location of portions of the component within a consistent but arbitrary frame of reference which is made clear by reference to the text and the associated Figures describing the component under discussion. Such terminology may include the words specifically mentioned above, derivatives thereof, and words of similar import.

As used herein, the term “integrated circuit component” refers to a packaged or unpackaged integrated circuit product. A packaged integrated circuit component comprises one or more integrated circuit dies mounted on a package substrate with the integrated circuit dies and package substrate encapsulated in a casing material, such as a metal, plastic, glass, or ceramic. In one example, a packaged integrated circuit component contains one or more processor units mounted on a substrate with an exterior surface of the substrate comprising a solder ball grid array (BGA). In one example of an unpackaged integrated circuit component, a single monolithic integrated circuit die comprises solder bumps attached to contacts on the die. The solder bumps allow the die to be directly attached to a printed circuit board. An integrated circuit component can comprise one or more of any computing system component described or referenced herein or any other computing system component, such as a processor unit (e.g., system-on-a-chip (SoC), processor core, graphics processor unit (GPU), accelerator, chipset processor), I/O controller, memory, or network interface controller.

Reference is now made to the drawings, which are not necessarily drawn to scale, wherein similar or same numbers may be used to designate same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

In the following description, for purposes of explanation, numerous specific details are set forth in order to provide a thorough understanding thereof. It may be evident, however, that the novel embodiments can be practiced without these specific details. In other instances, well known structures and devices are shown in block diagram form in order to facilitate a description thereof. The intention is to cover all modifications, equivalents, and alternatives within the scope of the claims.

FIGS. 2A-2F illustrate cross-sectional views of a simplified process of fabricating an example microelectronic structure comprising heterogeneous integrated dies with die-to-die I/O routing utilizing opposing surfaces of integrated circuit dies. Any of the fabrication methods or processes described herein, including method 300, may be performed using any suitable microelectronic fabrication techniques. For example, film deposition-such as depositing layers, filling (backfilling) portions of layers (e.g., filling removed portions of layers or removed layers), and filling via or contact openings—may be performed using any suitable deposition techniques, including, for example, chemical vapor deposition (CVD), metalorganic chemical vapor deposition (MOCVD), molecular beam epitaxy (MBE), atomic layer deposition (ALD), sputtering and/or physical vapor deposition (PVD). Moreover, layer patterning-such as dielectric or metal layer patterning—may be performed using any suitable techniques, such as photolithography-based patterning and etching (e.g., dry etching or wet etching). Furthermore, planarization of layers may be performed by using any suitable planarization technique, such as chemical-mechanical polishing (CMP).

FIG. 2A is a cross-sectional view of an example microelectronic structure comprising two integrated circuit dies attached to a carrier wafer. The structure 200 comprises a first integrated circuit die 224 and a second integrated circuit die 228 attached to a carrier wafer 204 by die bonding layers 258 attached to a bonding layer 208 located on the carrier wafer 204. The integrated circuit dies 224 and 228 can be known-good dies (KGDs) that have been transferred from a substrate on which the dies 224 and 228 were fabricated to the carrier wafer 204. The integrated circuit dies 224 and 228 are arranged laterally (that is, they are arranged in the x-y plane and do not vertically overlap) and are spaced laterally from each other. Each of the integrated circuit dies 224 and 228 comprise a transistor region 284, a first metallization region 286, a second metallization region 288, and a substrate region 260. The transistor region 284 is positioned between the first metallization region 286 and the second metallization region 288, and the second metallization region 288 is positioned between the transistor region 284 and the substrate region 260. The transistor region 284 comprises any type of transistor, such as field effect transistors (FETs) (e.g., planar FETs, FinFETs, nanoribbon FETs, forksheet FETs, and complementary FETs (CFETs)), spintronic transistors, or magnetoelectric tunnel junction transistors.

The metallization region 286 comprises conductive contacts 240 located on a surface 244 of the integrated circuit dies 224 and 228, metal layers 248 comprising metal lines 252, and vias 256. Each via 256 connects metal lines 252 of different metal layers or a metal line 252 to a conductive contact 240. Similarly, the metallization region 288 comprises conductive contacts 242 located on a surface 246 of the integrated circuit dies 224 and 228 (the surface 246 opposite to the surface 244), metal layers 250 comprising metal lines 254, and vias 262. Each via 262 connects metal lines 254 of different metal layers 250 or a metal line 254 to a conductive contact 242. The metallization regions 286 and 288 further comprise inter-layer dielectrics (ILDs) 296. The metallization regions 286 and 288 can route I/O signals and/or power signals from conductive contacts on a surface of the die to transistors in the transistor region 284. The substrate regions 260 provides mechanical support for the dies 224 and 228 during fabrication of the dies.

The integrated circuit dies 224 and 228 can be instances of the same integrated circuit design (e.g., instances of the same processor design or cache design). As such, the thicknesses of the first metallization regions 286 are substantially the same, the thicknesses of the transistor regions 284 are substantially the same, and the thicknesses of the second metallization regions 288 are substantially the same. As such, the surfaces 246 of the integrated circuit dies 224 and 228 are substantially coplanar and the surfaces 244 of the integrated circuit dies 224 and 228 are substantially coplanar. As can be seen in FIG. 2A, the thickness of the substrate regions 260 can be different. This can be due to, for example, coarse backside grinding that the integrated circuit dies 224 and 228 can be subjected to during electrical probing to determine whether the dies are KGDs.

In any of the embodiments described or referenced herein, the carrier wafer 204 can be a wafer, panel, or other structure that can provide mechanical support to integrated circuit dies. The carrier wafer 204 can comprise silicon, glass (e.g., amorphous solid glass, such as aluminosilicate, borosilicate, alumino-borosilicate, silica, and fused silica), sapphire, plastic, silicon carbide (SiC), gallium arsenide (GaAs) or other suitable material. In any of the embodiments described or referenced herein, a bonding layer (e.g., 208) bonding an integrated circuit die (e.g., 224, 228) to a carrier wafer (e.g., 204) can comprise a dielectric, such as an oxide, nitride, or another suitable dielectric. For example, the bonding layer 208 can comprise silicon and oxygen (e.g., SiOₓ, SiO₂), silicon and nitrogen (e.g., SiₓN_{y}, Si₃N₄), or silicon, carbon, and nitrogen (e.g., SiCN).

In any of the embodiments described or referenced herein, a transistor region (e.g., 284) comprising transistors in an integrated circuit die or the substrate region (e.g., 260, 219) of an integrated circuit die can comprise, for example, a crystalline substrate formed using a bulk silicon or a silicon-on-insulator (SOI) substructure. In some embodiments, a transistor region may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form a transistor region. Although a few examples of materials from which the transistor region may be formed are described here, any material that may serve as a foundation for an integrated circuit device may be used.

In any of the embodiments described or referenced herein, any inter-layer dielectrics positioned between or adjacent to metal layers (e.g., ILDs 296, 298) can comprise a suitable nitride or oxide, such as silicon nitride (Si₃N₄), silicon dioxide (SiO₂), carbon-doped silicon dioxide (C-doped SiO₂, also known as CDO or organosilicate glass, which is a material that comprises silicon, oxygen, and carbon), fluorine-doped silicon dioxide (F-doped SiO₂, also known as fluorosilicate glass, which is a material that comprises fluorine, silicon, and oxygen), hydrogen-doped silicon dioxide (H-doped SiO₂, which is a material that comprises silicon, oxygen, and hydrogen).

In any of the embodiments described or referenced herein, the metal lines (e.g., 216, 252, 254) in a metal layer in a metallization region can comprise copper, aluminum, titanium, tungsten, nickel, ruthenium, compounds or alloys thereof, combinations thereof, or another suitable material. In any of the embodiments described or referenced herein, the vias (e.g., 217, 256, 262) in a metallization region can comprise copper, tungsten, aluminum, titanium, titanium nitride, tantalum, tantalum nitride, compounds or alloys thereof, combinations thereof, or another suitable material. In any of the embodiments described or referenced herein, the conductive contacts located on a surface of an integrated circuit die can comprise copper, aluminum, gold, nickel, titanium, tungsten, compounds or alloys thereof, combinations thereof, or another suitable material.

FIG. 2B is a cross-sectional view of the example microelectronic structure of FIG. 2A after removal of the substrate regions of the integrated circuit dies. The substrate regions 260 of the integrated circuit dies 224 and 228 can be removed by, for example, etching and/or planarization.

FIG. 2C is a cross-sectional view of the example microelectronic structure of FIG. 2B after formation of a liner layer and a dielectric layer on the structure. A conformal liner layer 263 is formed on the structure 200 and covers the integrated circuit dies 224 and 228. The liner layer 263 can function as a sealant layer that protects the integrated circuit dies 224 and 228 from the processing steps used to form the dielectric layer 264. The dielectric layer 264 is formed on the liner layer 263 and fills the volumes between the integrated circuit dies 224 and 228. After formation of the dielectric layer 264, the liner layer 263 is positioned between the dielectric layer 264 and the integrated circuit dies 224 and 228. In some embodiments, the dielectric layer can be an oxide (a layer comprising oxygen).

In any of the embodiments described or referenced herein, the liner layer 263 can comprise silicon and oxygen (e.g., SiOₓ, SiO₂), silicon and nitrogen (e.g., Si₃N₄, SiₓN_{y}), silicon, carbon, and nitrogen (e.g., SiCN), or another suitable material. In any of the embodiments described or referenced herein, the dielectric layer 264 can comprise oxygen; silicon and oxygen (e.g., SiOₓ, SiO₂); or any other suitable dielectric material.

FIG. 2D is a cross-sectional view of the example microelectronic structure of FIG. 2C after thinning of the dielectric layer and planarization of the resulting top surface of the structure. Planarization of the structure 200 can result in the portions of the liner layer 263 being removed to expose the conductive contacts 242 at the surfaces 246 of the integrated circuit dies 224 and 228.

FIG. 2E is a cross-sectional view of the example microelectronic structure of FIG. 2D after formation of a redistribution layer region and through-dielectric vias. Through-dielectric vias 270 are formed in a region of the dielectric layer 264 positioned between the integrated circuit dies 224 and 228. Through-dielectric vias 270 extend through the dielectric layer 264 from a surface 272 of the dielectric layer 264 to an opposing surface 274 of the dielectric layer 264.

A redistribution layer region 281 is formed on the planarized top surfaces 246 of the integrated circuit dies 224 and 228 and the surface 272 of the dielectric layer 264. The redistribution layer region 281 comprises metal layers 283 comprising metal lines 285, and vias 287. Each via 287 connects metal lines 285 of different metal layers 283 or a metal line 285 to a conductive contact 242 of integrated circuit dies 224 and 248 or a through-dielectric via 270. The redistribution layer region 281 further comprises inter-layer dielectrics (ILDs) 289 positioned between the metal layers 283 and between the bottommost metal layer 283 and the surfaces 246 of the integrated circuit dies 224 and 228.

The redistribution layer region 281 enables the die-to-die routing of I/O signals between integrated circuit dies 224 and 228. For example, metal line 285a and vias 287a and 287b are part of I/O signal routing that provides a conductive path between conductive contact 242a on surface 246 of integrated circuit die 224 and conductive contact 242b on surface 246 of integrated circuit die 228. The redistribution layer region 281 can further provide the routing of power and ground signals to the integrated circuit dies 224 and 228.

In any of the embodiments described or referenced herein, the metal lines in a redistribution layer region can comprise copper, aluminum, or other suitable metal. In any of the embodiments described or referenced herein, the vias in a redistribution layer region can comprise copper, aluminum, tungsten, tantalum, tantalum nitride, or other suitable material. In any of the embodiments described or referenced herein, the ILDs in a redistribution layer region can comprise a dielectric material and may include a suitable nitride or oxide, such as silicon dioxide (SiO₂), carbon-doped silicon dioxide (C-doped SiO₂, also known as CDO or organosilicate glass, which is a material that comprises silicon, oxygen, and carbon), fluorine-doped silicon dioxide (F-doped SiO₂, also known as fluorosilicate glass, which is a material that comprises fluorine, silicon, and oxygen), hydrogen-doped silicon dioxide (H-doped SiO₂, which is a material that comprises silicon, oxygen, and hydrogen). In some embodiments, ILDs in a redistribution layer region comprise Ajinomoto Build-Up film (often referred to as ABF), which is a material that comprises an organic resin matrix with different types of fillers to control the coefficient of thermal expansion and/or electrical properties of the redistribution layer region ILDs (e.g., the dielectric constant (Dk), and/or dissipation factor (insertion loss) (Df)).

In any of the embodiments described or referenced herein, through-dielectric vias (e.g., 213, 215, 270) or through-silicon vias (e.g., 221) can comprise copper, tungsten, aluminum, tantalum, tantalum nitride, compounds or alloys thereof, combinations thereof, or other suitable materials.

The redistribution layer region 281 further comprises thermal via stacks 291. Thermal via stacks 291 comprise a vertical stack of one or more vias 287 and one or more metal lines 285 and cam provide a low thermal resistance path for heat generated by integrated circuit dies to pass flow the redistribution layer region 281. Any of the thermal via stacks can carry an I/O or power signal or be a “dummy” structure that does not carry an I/O or power signal. The thermal stacks 291 illustrated in FIG. 2E extend from a surface 246 of the integrated circuit dies 224 and 228 through the height of the redistribution layer region 281 to a thermal-mechanical substrate (not shown in FIG. 2E but illustrated in FIGS. 2F-2G). In other embodiments, a thermal via stack may extend only partially through the height of a redistribution layer region.

FIG. 2F is a cross-sectional view of the example microelectronic structure of FIG. 2E after attachment of a thermo-mechanical substrate to the structure. The thermal-mechanical substrate 299 can provide mechanical stability to the structure 200 after removal of the carrier wafer 204 from the structure 200. The substrate 299 can further function as a heat spreader that distributes heat generated by the integrated circuit dies 224 and 228 across the substrate 299 and provides a path for heat generated by the integrated circuit component dies 224 and 228 to reach an external surface of the integrated circuit component of which the structure 200 is part, where the heat can be dissipated into the local environment. In any of the embodiments described or referenced herein, the substrate 299 can comprise silicon, glass (e.g., amorphous solid glass, such as aluminosilicate, borosilicate, alumino-borosilicate, silica, and fused silica), sapphire, plastic, silicon carbide (SiC), gallium arsenide (GaAs) or other suitable material. The structure 200 illustrated in FIG. 2F can be considered a reconstituted wafer and integrated circuit dies 224 and 228 can be referred to as reconstituted dies.

FIG. 2G is a cross-sectional view of the example structure of FIG. 2F after removal of the carrier wafer and bonding layer, and attachment of a structure comprising integrated circuit dies. A structure 201 added to the structure 200 of FIG. 2F comprises integrated circuit dies 205 and 209, a dielectric layer 211 comprising a portion positioned between the integrated circuit dies 205 and 209, and through-dielectric vias 213 and 215. The integrated circuit die 205 is positioned laterally to the die 209. The integrated circuit dies 205 and 209 are stacked vertically relative to the integrated circuit dies 224 and 229, respectively. Although the dies 205 and 209 are illustrated as fully overlapping vertically with the dies 224 and 228, respectively, in some embodiments, integrated circuit dies 205 and 209 can partially vertically overlap with dies 224 and 228, respectively.

The integrated circuit dies 205 and 209 can be instances of the same integrated circuit design (e.g., instances of the same core or cache design) and can be instances of the same or different integrated circuit design that the integrated circuit dies 224 and 228 are instances of. For example, in some embodiments, the integrated circuit dies 224 and 228 can be instances of the same core design and integrated circuit dies 205 and 209 can be instances of the same cache design. The integrated circuit dies 205 and 209 can also be formed using the same or different semiconductor manufacturing process node used to form the integrated circuit dies 224 and 228. Having homogeneous integrated circuit dies in the structure 201 can result in a simpler processing flow relative to a structure comprising heterogeneous dies due to, for example, the uniformity in attaching integrated circuit dies 224 and 228 to the integrated circuit dies 205 and 209 (having to attach to the same bond pad size, shape, density, etc.). The simpler flow enabled by homogeneous integrated circuit dies in the structure 201 may also result in improved yield. As the integrated circuit dies 205 and 209 can be a different integrated circuit type, design, and/or be manufactured from a different processing node than the integrated circuit dies 224 and 228, an integrated circuit component comprising the structure 200 illustrated in FIG. 2G can be considered to comprise heterogeneous dies.

Each of the integrated circuit dies 205 and 209 comprises a transistor region 207, conductive contacts 241 located on a surface 245, metal layers 214 comprising metal lines 216, vias 217, ILDs 298 positioned between the metal layers 214, through-silicon vias 221, and a substrate region 219. Each via 217 connects metal lines 216 of different metal layers 214 or a metal line 216 to a conductive contact 241. The transistor region 207 is positioned between the metal layers 214 and the substrate region 219. The transistor region 207 comprises any type of transistor, such as field effect transistors (e.g., planar FETs, FinFETs, nanoribbon FETs, forksheet FETs, and complementary FETs (CFETs)). Through-silicon vias 221 extend through the substrate region 219 to a surface 225 of the integrated circuit die. The metal lines 216, vias 217, and through-silicon vias 221 route I/O signals and/or power signals from the conductive contacts 241 on 245 of the die to transistors in the transistor region 207.

Die bonding layers 247 are positioned adjacent to the surfaces 245 of the integrated circuit dies 205 and 207. The conductive contacts 241 of integrated circuit dies 205 and 205 are attached to conductive contact 240 of integrated circuit dies 224 and 228 by vias 229 and 231 extending through the die bonding layers 247 and 258, respectively. Vias 229 and 231 can be formed in the die bonding layers 247 and 258, respectively, prior to attachment of the structure 201 to the structure 200 illustrated in FIG. 2F.

Through-dielectric vias 213 and 215 extend from a bottom surface 271 to a top surface 273 of a region of the dielectric layer 211. Through-dielectric vias 213 connect to conductive contacts 240 by vias 229 in the die bonding layer 247 and through-dielectric vias 215 attach to through-dielectric vias 270. The through-dielectric vias 215 are illustrated as attaching to through-dielectric vias 270 by vias 233 in the liner layer, but in other embodiments, the through-dielectric vias 270 extend through the liner layer 263 and the through-dielectric vias 215 attach directly to the through-dielectric vias 270. In embodiments whether the liner layer 263 comprises vias 233, the vias 233 can be formed in the liner layer 263 prior to attachment of the structure 201 to the structure 200 illustrated in FIG. 2F.

In some embodiments, the structure 201 can be attached to the structure 200 via hybrid bonding, through which vias 229 are bonded to vias 231, through-dielectric vias 213 are bonded to vias 229, through-dielectric vias 215 are bonded to vias 233 (or directly bonded to through-dielectric vias 270), and the dielectric layer 211 is bonded to the die bonding layers 258 and portions of the liner layer 263.

In some embodiments, the structure 201 can be part of a reconstituted wafer formed with a process comprising steps similar to some of those illustrated in FIGS. 2A-2D. That is, the integrated circuit dies 205 and 229 can be known-good dies formed on a growth substrate and transferred to a carrier wafer. A liner layer and oxide can then be growth on the integrated circuit dies 205 and 229, the resulting structure planarized and attached to a substrate providing mechanical integrity to the before removal of the carrier wafer, resulting in a reconstituted wafer. The through-dielectric vias 213 and 215 and vias 231 can be formed in the reconstituted wafer before attachment of the reconstituted wafer to the structure 200 as illustrated in FIG. 2E. The substrate of the reconstituted wafer can then be thinned to expose the through-silicon vias 221 and the through-dielectric vias 213 and 215. Conductive contacts 257 can then be formed on the exposed through-silicon vias 221 and the through-dielectric vias 213 and 215 to form the structure 200 illustrated in FIG. 2G. The conductive contacts 257 can be solder balls, pads, bumps, microbumps, pillars, micropillars, or other suitable structures. The conductive contacts 257 can comprise copper, silver, lead, tin, nickel, titanium, or another suitable material. The conductive contacts 257 can attach to a package substrate (not shown) that is part of an integrated circuit component that the structure 200 illustrated in FIG. 2G can be part of.

In some embodiments, the structure 200 as illustrated in FIG. 2F can be a wafer or a structure that has been singulated from a wafer. In the former case, the attachment of the structure 200 to the structure 201 can be considered to be a chip-on-wafer (CoW) assembly process, and in the latter, a wafer-on-wafer (WoW) assembly process.

The structure 200 as illustrated in FIG. 2G enables die-to-die I/O signal routing using opposing die surfaces in an integrated circuit component comprising vertically stacked heterogeneous integrated circuit dies. For example, the redistribution layer region 281 attached to the top surface 246 of integrated circuit die 224 enables die-to-die I/O signal routing between integrated circuit dies 224 and 228, and the attachment of the conductive contacts 240 on the bottom surface of the integrated circuit die 224 to the conductive contacts 241 on the top surface of the integrated circuit die 205 enables die-to-die I/O signal routing between the integrated circuit dies 224 and 205.

It is to be noted that the structure 200 illustrated in FIG. 2G does not comprise embedded bridges to provide the routing of signals between integrated circuit dies that are positioned laterally to each other. That is, there are no embedded bridges located in the redistribution layer region 281. Put another way, there are no embedded bridges in any integrated circuit component that the structure 200 illustrated in FIG. 2G can be a part of in a volume extending from the surfaces of the integrated circuit dies 224 and 228 in a direction away from the transistor regions 284 toward an outer surface of such an integrated circuit component.

It is to be further noted that the absence of an embedded bridge in the portion of the dielectric layer 211 positioned between the integrated circuit dies 205 and 209 allows for the presence of more through-dielectric vias that can be used for power delivery to the integrated circuit dies 224 and 228. That is, if an embedded bridge were present in the portion of the dielectric layer 211 located between the dies 224 and 228, it may prevent the placement of through-dielectric vias 215 and 213 located between the integrated circuit dies 224 and 228. The absence of embedded bridges in the dielectric layer 211 can further allow through-dielectric vias 215 to be added that can connect to through-dielectric vias 270 in the dielectric layer 264. Through-dielectric vias 215 and 270 can together provide for further delivery of power signals to the integrated circuit dies 224 and 228 and provide robust power signal delivery to these dies. Through-dielectric vias 215 and 270 can further provide for the routing of I/O signals from the integrated circuit dies 224 and 228 to the conductive contacts 257.

In any of the embodiments described or referenced herein, the dielectric layer 211 can comprise silicon and oxygen (e.g., SiOₓ, SiO₂), silicon and nitrogen (e.g., Si₃N₄, SiₓN_{y}), silicon, carbon, and nitrogen (e.g., SiCN), or another suitable material.

FIG. 2G illustrates one possible structure in which die-to-die routing between integrated circuit dies utilizes opposite integrated circuit die surfaces. In other embodiments, a redistribution layer region can be positioned between integrated circuit dies in different layers of an integrated circuit component. For example, a redistribution layer region could be positioned between integrated circuit dies 224 and 228 and integrated circuit dies 205 and 209 that provide die-to-die routing from die 224 to die 205 and die 228 to die 209. In yet other embodiments, an integrated circuit component can comprise more than two layers of integrated circuit dies, and the die-to-die routing utilizing opposing surfaces of an integrated circuit dies can occur on integrated circuit dies located on different layers.

The integrated circuit components and microelectronic structures or assemblies described herein can be used in any processor unit or integrated circuit component described or referenced herein. A heterogeneous integrated circuit component comprising die-to-die routing utilizing opposing surfaces on an integrated circuit die can be attached to a printed circuit board (motherboard, mainboard). In some embodiments, one or more additional integrated circuit components or other components (e.g., battery, memory, antenna) can be attached to the printed circuit board. In some embodiments, the printed circuit board and the integrated circuit component can be located in a computing device that comprises a housing that encloses the printed circuit board and the integrated circuit component.

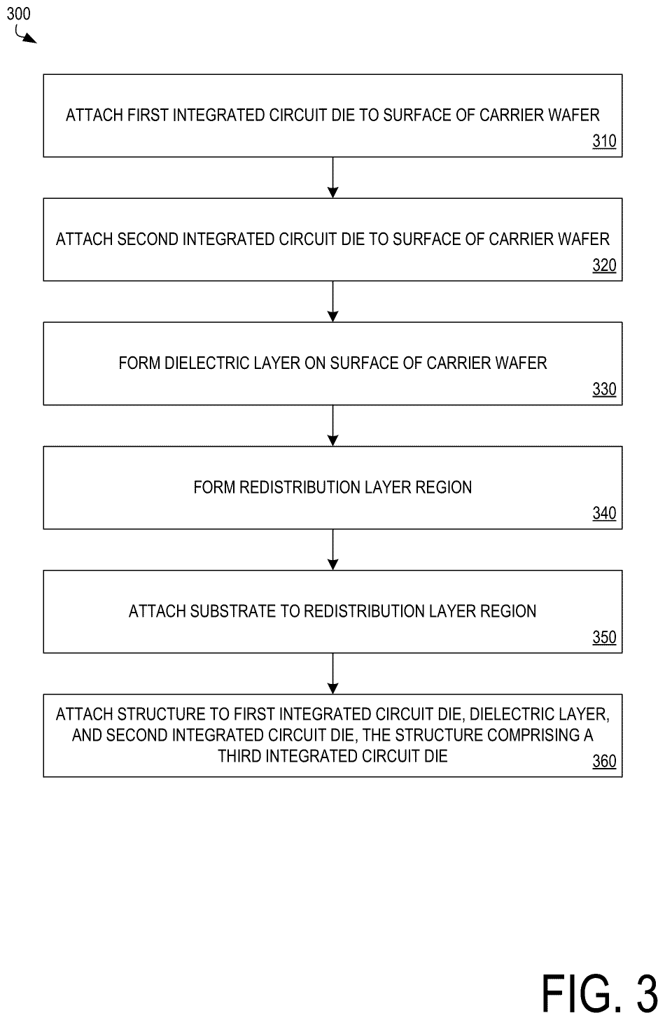

FIG. 3 is an example method of forming a structure comprising die-to-die routing utilizing opposing surfaces of an integrated circuit die. The method 300 can be performed by, for example, an integrated circuit component manufacture. At 310, a first integrated circuit die is attached to a surface of a carrier wafer, the first integrated circuit die comprising a first transistor region, a first layer comprising metal, and a second layer comprising metal, wherein the first transistor region is positioned between the first layer and the second layer. At 320, a second integrated circuit die is attached to the surface of the carrier wafer, the second integrated circuit die comprising a second transistor region, a third layer comprising metal, and a fourth layer comprising metal, wherein the second transistor region is positioned between the third layer and the fourth layer. At 330, a dielectric layer is formed on the surface of the carrier wafer, a region of the dielectric layer positioned between the first integrated circuit die and the second integrated circuit die. At 340, a redistribution layer region is formed on the first integrated circuit die, the second integrated circuit die and the region of the dielectric layer. At 350, a substrate is attached to the redistribution layer region. At 350, the carrier wafer is separated from the first integrated circuit die, the second integrated circuit die, and the region of the dielectric layer. At 360, a structure is attached to the first integrated circuit die, the region of the dielectric layer, and the second integrated circuit die, the structure comprising a third integrated circuit die, wherein attaching the structure comprising attaching a portion of the third integrated circuit die to at least a portion of the first integrated circuit die.

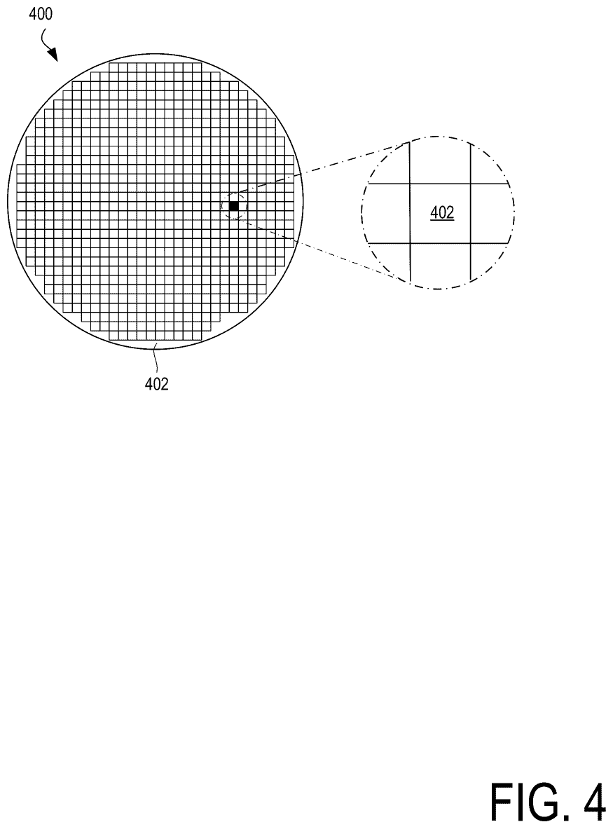

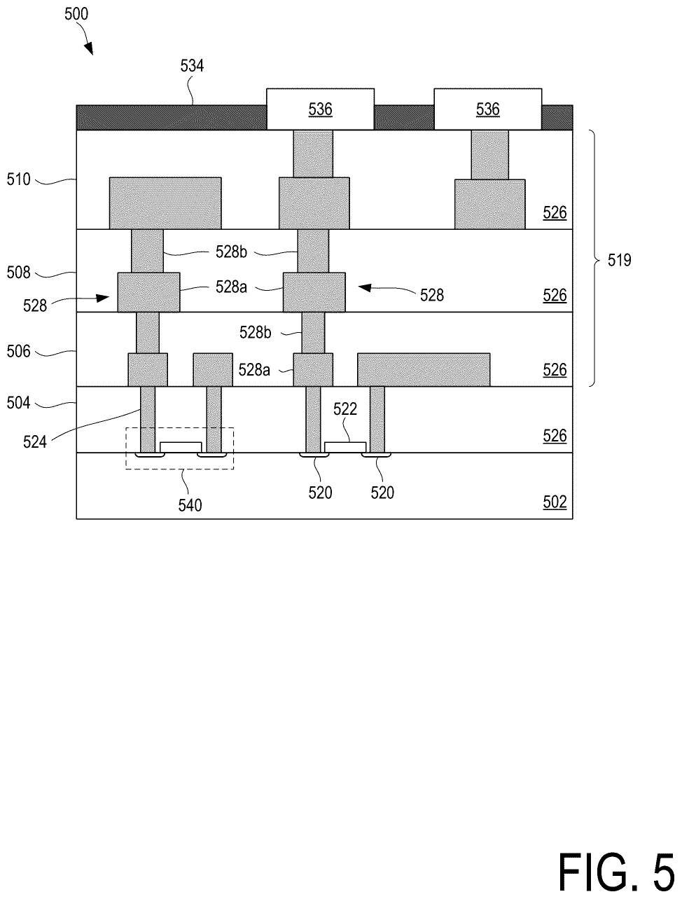

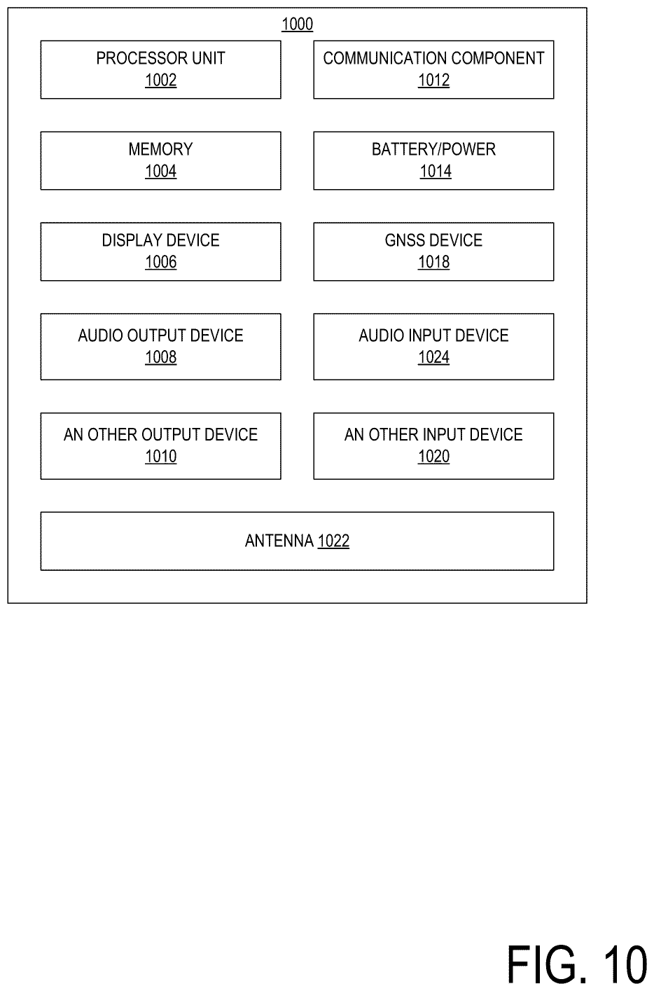

FIG. 4 is a top view of a wafer 400 and dies 402 that may be included in any of the microelectronic assemblies or structures disclosed herein (e.g., structures 200, 201). The wafer 400 may be composed of semiconductor material and may include one or more dies 402 having integrated circuit structures formed on a surface of the wafer 400. The individual dies 402 may be a repeating unit of an integrated circuit product that includes any suitable integrated circuit. After the fabrication of the semiconductor product is complete, the wafer 400 may undergo a singulation process in which the dies 402 are separated from one another to provide discrete “chips” of the integrated circuit product. The die 402 may be any of the integrated circuit dies disclosed herein (e.g., 205, 209, 224, 229). The die 402 may include one or more transistors (e.g., some of the transistors 540 of FIG. 5, discussed below), supporting circuitry to route electrical signals to the transistors, passive components (e.g., signal traces, resistors, capacitors, or inductors), and/or any other integrated circuit components. In some embodiments, the wafer 400 or the die 402 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 402. For example, a memory array formed by multiple memory devices may be formed on a same die 402 as a processor unit (e.g., the processor unit 1002 of FIG. 10) or other logic that is configured to store information in the memory devices or execute instructions stored in the memory array. Various ones of the microelectronic assemblies or structures disclosed herein may be manufactured using a die-to-wafer assembly technique in which some dies are attached to a wafer 400 that include others of the dies, and the wafer 400 is subsequently singulated.

FIG. 5 is a cross-sectional side view of an integrated circuit device 500 that may be included in any of the microelectronic assemblies or structures disclosed herein (e.g., in any of the dies 205, 209, 224, 228). One or more of the integrated circuit devices 500 may be included in one or more dies 402 (FIG. 4). The integrated circuit device 500 may be formed on a die substrate 502 (e.g., the wafer 400 of FIG. 4) and may be included in a die (e.g., the die 402 of FIG. 4). The die substrate 502 may be a semiconductor substrate composed of semiconductor material systems including, for example, n-type or p-type materials systems (or a combination of both). The die substrate 502 may include, for example, a crystalline substrate formed using a bulk silicon or a silicon-on-insulator (SOI) substructure. In some embodiments, the die substrate 502 may be formed using alternative materials, which may or may not be combined with silicon, that include, but are not limited to, germanium, carbon, indium antimonide, lead telluride, indium arsenide, indium phosphide, gallium arsenide, or gallium antimonide. Further materials classified as group II-VI, III-V, or IV may also be used to form the die substrate 502. Although a few examples of materials from which the die substrate 502 may be formed are described here, any material that may serve as a foundation for an integrated circuit device 500 may be used. The die substrate 502 may be part of a singulated die (e.g., the dies 402 of FIG. 4) or a wafer (e.g., the wafer 400 of FIG. 4).

The integrated circuit device 500 may include one or more device layers 504 disposed on the die substrate 502. The device layer 504 may include features of one or more transistors 540 (e.g., metal oxide semiconductor field-effect transistors (MOSFETs)) formed on the die substrate 502. The transistors 540 may include, for example, one or more source and/or drain (S/D) regions 520, a gate 522 to control current flow between the S/D regions 520, and one or more S/D contacts 524 to route electrical signals to/from the S/D regions 520. The transistors 540 may include additional features not depicted for the sake of clarity, such as device isolation regions, gate contacts, and the like. The transistors 540 are not limited to the type and configuration depicted in FIG. 5 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

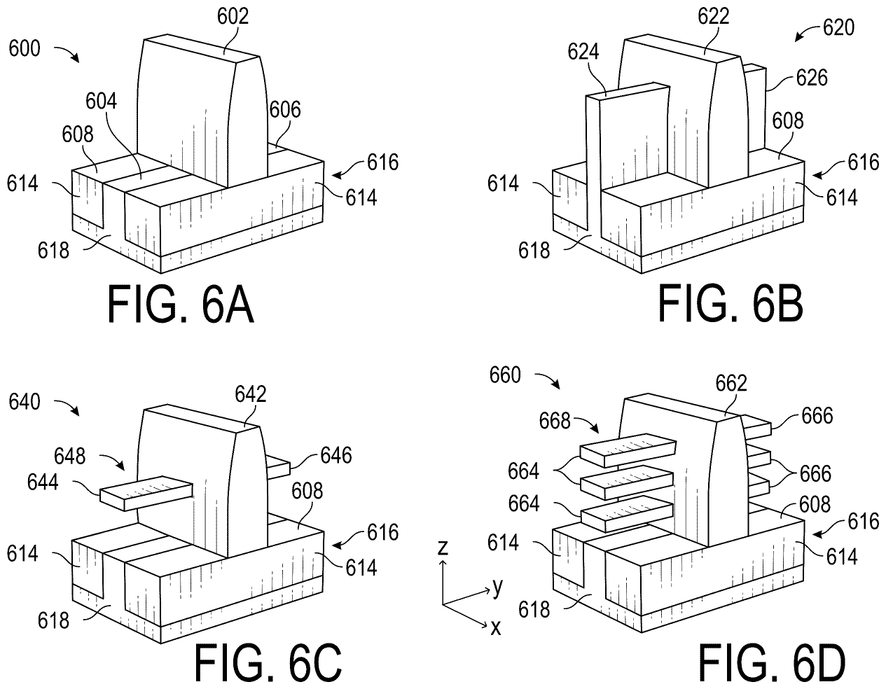

FIGS. 6A-6D are simplified perspective views of example planar, FinFET, gate-all-around, and stacked gate-all-around transistors. The transistors illustrated in FIGS. 6A-6D are formed on a substrate 616 having a surface 608. Isolation regions 614 separate the source and drain regions of the transistors from other transistors and from a bulk region 618 of the substrate 616.

FIG. 6A is a perspective view of an example planar transistor 600 comprising a gate 602 that controls current flow between a source region 604 and a drain region 606. The transistor 600 is planar in that the source region 604 and the drain region 606 are planar with respect to the substrate surface 608.

FIG. 6B is a perspective view of an example FinFET transistor 620 comprising a gate 622 that controls current flow between a source region 624 and a drain region 626. The transistor 620 is non-planar in that the source region 624 and the drain region 626 comprise “fins” that extend upwards from the substrate surface 608. As the gate 622 encompasses three sides of the semiconductor fin that extends from the source region 624 to the drain region 626, the transistor 620 can be considered a tri-gate transistor. FIG. 6B illustrates one S/D fin extending through the gate 622, but multiple S/D fins can extend through the gate of a FinFET transistor.

FIG. 6C is a perspective view of a gate-all-around (GAA) transistor (GAAFET) 640 comprising a gate 642 that controls current flow between a source region 644 and a drain region 646 of a strip 648 comprising a semiconductor (semiconductor strip). The transistor 640 is non-planar in that the strip 648 is elevated from the substrate surface 608.

FIG. 6D is a perspective view of a GAA transistor 660 comprising a gate 662 that controls current flow between source regions 664 and drain regions 666 of multiple elevated semiconductor strips 668. The transistor 660 is a stacked GAA transistor as the gate controls the flow of current between multiple elevated S/D regions stacked on top of each other. The transistors 640 and 660 can be referred to as gate-all-around transistors as the gates encompass all sides of the portions of the semiconductor strips that extend from the source regions to the drain regions. The transistors 640 and 660 can alternatively be referred to as nanowire, nanosheet, or nanoribbon transistors and the semiconductor strips that pass through the gate region can be referred to as nanowires, nanowires, or nanoribbons.

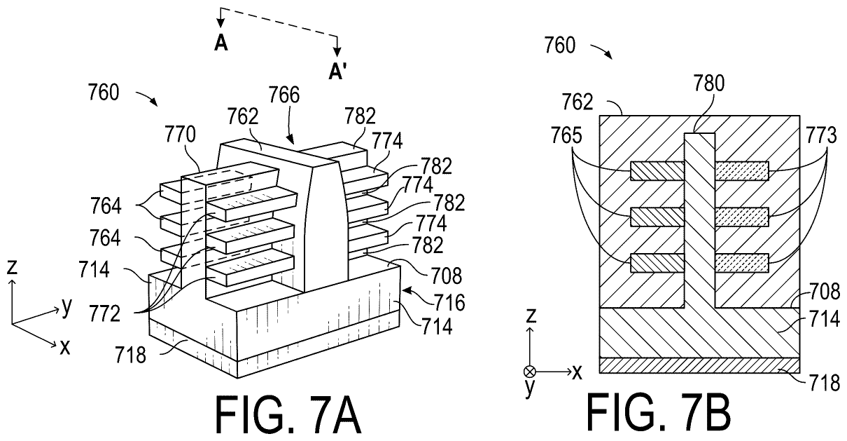

FIGS. 7A and 7B are simplified perspective and cross-sectional views of example forksheet gate-all-around transistors. The forksheet FETs 760 is formed on a substrate 716 having a surface 708. The substrate 716 comprises an isolation region 714 located on top of a bulk region 718. The forksheet FETs 760 are similar to the stacked GAA transistor 660 of FIG. 6D, but with an isolation region 770 located between stacked n-type and p-type source regions and stacked n-type and p-type drain regions. The forksheet FETs 760 comprise a gate 762 that controls flow between multiple n-type elevated source regions 764 and multiple n-type elevated drain regions 766, and multiple p-type elevated source regions 774 and multiple p-type elevated drain regions 772. FIG. 7B is a cross-sectional view of the forksheet FETs 760 taken along the line A-A′ of FIG. 7A. Channel regions 765 connect n-type source regions 764 to n-type drain regions 766, channel regions 773 connect p-type source regions 774 to p-type drain regions 772, and isolation region 780 separates the channel regions 765 from the channel regions 773 and connects isolation region 770 to isolation region 782. Thus, the forksheet FETs 760 comprise an n-type transistor comprising n-type source regions 764, channel region 765, n-type drain regions 766 and gate 762; and a p-type transistor comprising p-type source regions 772, channel regions 774, p-type drain regions 773, and gate 762. The gate 762 is shared by the forksheet FETs 760. Forksheet FETs 760 can provide for reduced spacing between n-type and p-type S/D regions in adjacent transistors relative to GAA transistors and can thus allow for increased transistor density relative to GAA transistors or increased active transistor width at the same transistor density as GAA transistors.

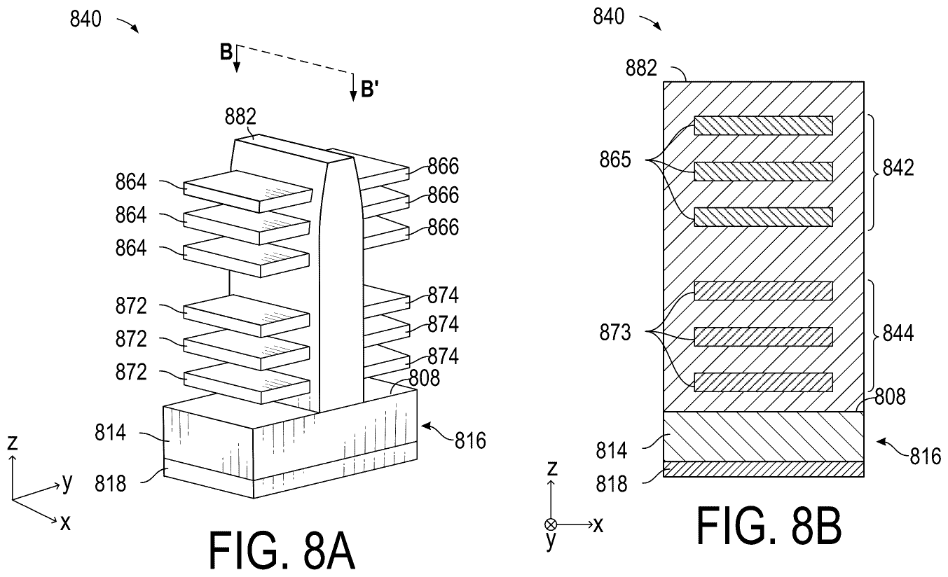

FIGS. 8A-14B are simplified perspective and cross-sectional views, respectively, of an example complementary field-effect-transistor (CFET) architecture. FIG. 8B is a cross-sectional view of the CFET architecture 840 taken along the line B-B′ of FIG. 8A. The CFET architecture 840 comprises vertically stacked gate-all-around transistors 842 and 844. In FIGS. 8A and 8B, transistor 842 is an n-type transistor and transistor 844 is a p-type transistor, but in other embodiments, a CFET architecture can comprise an n-type transistor located above a p-type transistor. The transistors 842 and 844 are formed on a substrate 816 having a surface 808. The substrate 816 comprises an isolation region 814 located on top of a bulk region 818.

The n-type and p-type transistors 842 and 844 comprise a gate 882 shared by both transistors that control current flow between multiple elevated source regions and multiple elevated drain regions 874. The n-type transistor 842 comprises n-type source regions 872 connected to n-type drain regions 874 by channel regions 873 and the p-type transistor 844 comprises p-type source regions 864 connected to p-type drain regions 866 by channel regions 865. The transistor stacking employed by the CFET architecture can provide for improved transistor density in the x- and y-dimensions or increased transistor width at the same transistor density relative to other gate-all-around transistor architectures, such as those illustrated in FIGS. 6D, 7A, and 7B. In some embodiments, the CFET architecture 840 can be formed monolithically, with the upper and lower transistors being formed on the same substrate, or sequentially, with the lower transistor (e.g., 840) formed on a first substrate and the upper transistor (e.g., 842) formed on a second substrate, with the upper transistor integrated with the lower transistor through transfer of the upper transistor from the second substrate to the first substrate.

Returning to FIG. 5, a transistor 540 may include a gate 522 formed of at least two layers, a gate dielectric, and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be performed on the gate dielectric to improve its quality when a high-k material is used.

The gate electrode may be formed on the gate dielectric and may include at least one p-type work function metal or n-type work function metal, depending on whether the transistor 540 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 540 along the source-channel-drain direction, the gate electrode may consist of a U-shaped structure that includes a bottom portion substantially parallel to the surface of the die substrate 502 and two sidewall portions that are substantially perpendicular to the top surface of the die substrate 502. In other embodiments, at least one of the metal layers that form the gate electrode may simply be a planar layer that is substantially parallel to the top surface of the die substrate 502 and does not include sidewall portions substantially perpendicular to the top surface of the die substrate 502. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 520 may be formed within the die substrate 502 adjacent to the gate 522 of individual transistors 540. The S/D regions 520 may be formed using an implantation/diffusion process or an etching/deposition process, for example. In the former process, dopants such as boron, aluminum, antimony, phosphorous, or arsenic may be ion-implanted into the die substrate 502 to form the S/D regions 520. An annealing process that activates the dopants and causes them to diffuse farther into the die substrate 502 may follow the ion-implantation process. In the latter process, the die substrate 502 may first be etched to form recesses at the locations of the S/D regions 520. An epitaxial deposition process may then be performed to fill the recesses with material that is used to fabricate the S/D regions 520. In some implementations, the S/D regions 520 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 520 may be formed using one or more alternate semiconductor materials such as germanium or a group III-V material or alloy. In further embodiments, one or more layers of metal and/or metal alloys may be used to form the S/D regions 520.

Electrical signals, such as power and/or input/output (I/O) signals, may be routed to and/or from the devices (e.g., transistors 540) of the device layer 504 through one or more interconnect layers disposed on the device layer 504 (illustrated in FIG. 5 as interconnect layers 506-510). For example, electrically conductive features of the device layer 504 (e.g., the gate 522 and the S/D contacts 524) may be electrically coupled with the interconnect structures 528 of the interconnect layers 506-510. The one or more interconnect layers 506-510 may form a metallization stack (also referred to as an “ILD stack”) 519 of the integrated circuit device 500.

The interconnect structures 528 may be arranged within the interconnect layers 506-510 to route electrical signals according to a wide variety of designs; in particular, the arrangement is not limited to the particular configuration of interconnect structures 528 depicted in FIG. 5. Although a particular number of interconnect layers 506-510 is depicted in FIG. 5, embodiments of the present disclosure include integrated circuit devices having more or fewer interconnect layers than depicted.

In some embodiments, the interconnect structures 528 may include lines 528a and/or vias 528b filled with an electrically conductive material such as a metal. The lines 528a may be arranged to route electrical signals in a direction of a plane that is substantially parallel with a surface of the die substrate 502 upon which the device layer 504 is formed. For example, the lines 528a may route electrical signals in a direction in and out of the page and/or in a direction across the page from the perspective of FIG. 5. The vias 528b may be arranged to route electrical signals in a direction of a plane that is substantially perpendicular to the surface of the die substrate 502 upon which the device layer 504 is formed. In some embodiments, the vias 528b may electrically couple lines 528a of different interconnect layers 506-510 together.

The interconnect layers 506-510 may include a dielectric material 526 disposed between the interconnect structures 528, as shown in FIG. 5. In some embodiments, dielectric material 526 disposed between the interconnect structures 528 in different ones of the interconnect layers 506-510 may have different compositions; in other embodiments, the composition of the dielectric material 526 between different interconnect layers 506-510 may be the same. The device layer 504 may include a dielectric material 526 disposed between the transistors 540 and a bottom layer of the metallization stack as well. The dielectric material 526 included in the device layer 504 may have a different composition than the dielectric material 526 included in the interconnect layers 506-510; in other embodiments, the composition of the dielectric material 526 in the device layer 504 may be the same as a dielectric material 526 included in any one of the interconnect layers 506-510.

A first interconnect layer 506 (referred to as Metal 1 or “M1”) may be formed directly on the device layer 504. In some embodiments, the first interconnect layer 506 may include lines 528a and/or vias 528b, as shown. The lines 528a of the first interconnect layer 506 may be coupled with contacts (e.g., the S/D contacts 524) of the device layer 504. The vias 528b of the first interconnect layer 506 may be coupled with the lines 528a of a second interconnect layer 508.

The second interconnect layer 508 (referred to as Metal 2 or “M2”) may be formed directly on the first interconnect layer 506. In some embodiments, the second interconnect layer 508 may include via 528b to couple the lines 528 of the second interconnect layer 508 with the lines 528a of a third interconnect layer 510. Although the lines 528a and the vias 528b are structurally delineated with a line within individual interconnect layers for the sake of clarity, the lines 528a and the vias 528b may be structurally and/or materially contiguous (e.g., simultaneously filled during a dual-damascene process) in some embodiments.

The third interconnect layer 510 (referred to as Metal 3 or “M3”) (and additional interconnect layers, as desired) may be formed in succession on the second interconnect layer 508 according to similar techniques and configurations described in connection with the second interconnect layer 508 or the first interconnect layer 506. In some embodiments, the interconnect layers that are “higher up” in the metallization stack 519 in the integrated circuit device 500 (i.e., farther away from the device layer 504) may be thicker than the interconnect layers that are lower in the metallization stack 519, with lines 528a and vias 528b in the higher interconnect layers being thicker than those in the lower interconnect layers.

The integrated circuit device 500 may include a solder resist material 534 (e.g., polyimide or similar material) and one or more conductive contacts 536 formed on the interconnect layers 506-510. In FIG. 5, the conductive contacts 536 are illustrated as taking the form of bond pads. The conductive contacts 536 may be electrically coupled with the interconnect structures 528 and configured to route the electrical signals of the transistor(s) 540 to external devices. For example, solder bonds may be formed on the one or more conductive contacts 536 to mechanically and/or electrically couple an integrated circuit die including the integrated circuit device 500 with another component (e.g., a printed circuit board). The integrated circuit device 500 may include additional or alternate structures to route the electrical signals from the interconnect layers 506-510; for example, the conductive contacts 536 may include other analogous features (e.g., posts) that route the electrical signals to external components. The conductive contacts 536 may serve as the conductive contacts 240, 241, or 242, as appropriate.

In some embodiments in which the integrated circuit device 500 is a double-sided die (e.g., 224, 229), the integrated circuit device 500 may include another metallization stack (not shown) on the opposite side of the device layer(s) 504. This metallization stack may include multiple interconnect layers as discussed above with reference to the interconnect layers 506-510, to provide conductive pathways (e.g., including conductive lines and vias) between the device layer(s) 504 and additional conductive contacts (not shown) on the opposite side of the integrated circuit device 500 from the conductive contacts 536. These additional conductive contacts may serve as the conductive contacts 240 or 242, as appropriate.

In other embodiments in which the integrated circuit device 500 is a double-sided die, the integrated circuit device 500 may include one or more through silicon vias (TSVs) through the die substrate 502; these TSVs may make contact with the device layer(s) 504, and may provide conductive pathways between the device layer(s) 504 and additional conductive contacts (not shown) on the opposite side of the integrated circuit device 500 from the conductive contacts 536. In some embodiments, TSVs extending through the substrate can be used for routing power and ground signals from conductive contacts on the opposite side of the integrated circuit device 500 from the conductive contacts 536 to the transistors 540 and any other components integrated into the die 500, and the metallization stack 519 can be used to route I/O signals from the conductive contacts 536 to transistors 540 and any other components integrated into the die 500.

Multiple integrated circuit devices 500 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

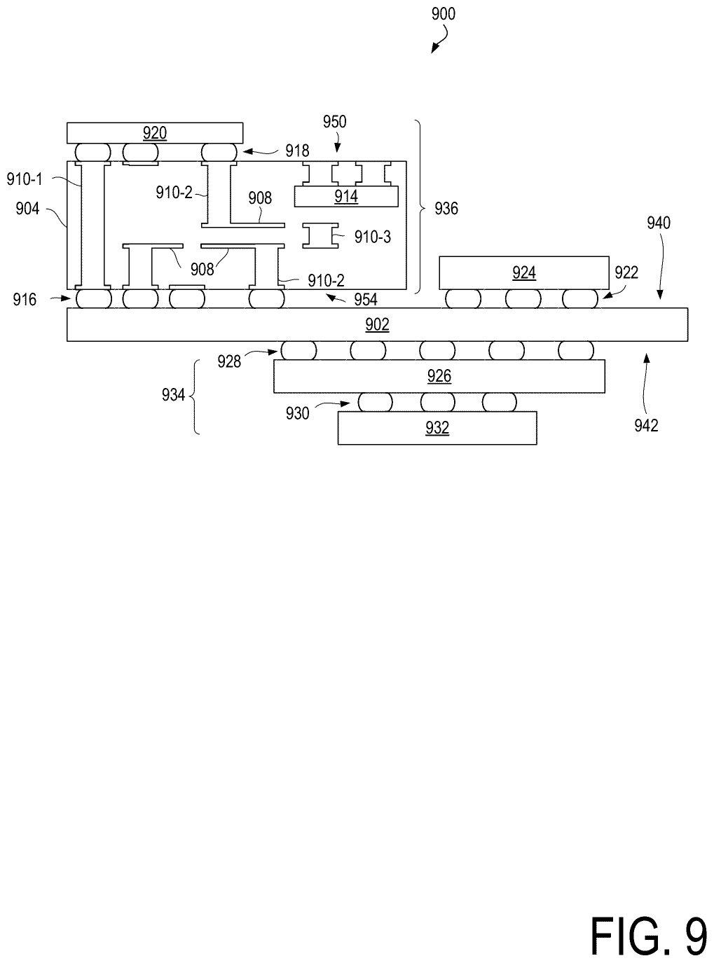

FIG. 9 is a cross-sectional side view of an integrated circuit device assembly 900 that may include any of the microelectronic assemblies or structures disclosed herein. The integrated circuit device assembly 900 includes a number of components disposed on a circuit board 902 (which may be a motherboard, system board, mainboard, etc.). The integrated circuit device assembly 900 includes components disposed on a first face 940 of the circuit board 902 and an opposing second face 942 of the circuit board 902; generally, components may be disposed on one or both faces 940 and 942. Any of the integrated circuit components discussed below with reference to the integrated circuit device assembly 900 may take the form of an integrated circuit component comprising any of the microelectronic assemblies or structures disclosed herein.

In some embodiments, the circuit board 902 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 902. In other embodiments, the circuit board 902 may be a non-PCB substrate. The integrated circuit device assembly 900 illustrated in FIG. 9 includes a package-on-interposer structure 936 coupled to the first face 940 of the circuit board 902 by coupling components 916. The coupling components 916 may electrically and mechanically couple the package-on-interposer structure 936 to the circuit board 902, and may include solder balls (as shown in FIG. 9), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. The coupling components 916 may serve as the coupling components illustrated or described for any of the substrate assembly or substrate assembly components described herein, as appropriate.

The package-on-interposer structure 936 may include an integrated circuit component 920 coupled to an interposer 904 by coupling components 918. The coupling components 918 may take any suitable form for the application, such as the forms discussed above with reference to the coupling components 916. Although a single integrated circuit component 920 is shown in FIG. 9, multiple integrated circuit components may be coupled to the interposer 904; indeed, additional interposers may be coupled to the interposer 904. The interposer 904 may provide an intervening substrate used to embedded bridge the circuit board 902 and the integrated circuit component 920.

The integrated circuit component 920 may be a packaged or unpackaged integrated circuit product that includes one or more integrated circuit dies (e.g., the die 402 of FIG. 4, the integrated circuit device 500 of FIG. 5) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 920, a single monolithic integrated circuit die comprises solder bumps attached to contacts on the die. The solder bumps allow the die to be directly attached to the interposer 904. The integrated circuit component 920 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 920 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 920 comprises multiple integrated circuit dies, the dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 920 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon embedded bridges embedded in the package substrate (such as Intel® embedded multi-die interconnect embedded bridges (EMIBs)), or combinations thereof.

Generally, the interposer 904 may spread connections to a wider pitch or reroute a connection to a different connection. For example, the interposer 904 may couple the integrated circuit component 920 to a set of ball grid array (BGA) conductive contacts of the coupling components 916 for coupling to the circuit board 902. In the embodiment illustrated in FIG. 9, the integrated circuit component 920 and the circuit board 902 are attached to opposing sides of the interposer 904; in other embodiments, the integrated circuit component 920 and the circuit board 902 may be attached to a same side of the interposer 904. In some embodiments, three or more components may be interconnected by way of the interposer 904.

In some embodiments, the interposer 904 may be formed as a PCB, including multiple metal layers separated from one another by layers of dielectric material and interconnected by electrically conductive vias. In some embodiments, the interposer 904 may be formed of an epoxy resin, a fiberglass-reinforced epoxy resin, an epoxy resin with inorganic fillers, a ceramic material, or a polymer material such as polyimide. In some embodiments, the interposer 904 may be formed of alternate rigid or flexible materials that may include the same materials described above for use in a semiconductor substrate, such as silicon, germanium, and other group III-V and group IV materials. The interposer 904 may include metal interconnects 908 and vias 910, including but not limited to through hole vias 910-1 (that extend from a first face 950 of the interposer 904 to a second face 954 of the interposer 904), blind vias 910-2 (that extend from the first or second faces 950 or 954 of the interposer 904 to an internal metal layer), and buried vias 910-3 (that connect internal metal layers).

In some embodiments, the interposer 904 can comprise a silicon interposer. Through silicon vias (TSV) extending through the silicon interposer can connect connections on a first face of a silicon interposer to an opposing second face of the silicon interposer. In some embodiments, an interposer 904 comprising a silicon interposer can further comprise one or more routing layers to route connections on a first face of the interposer 904 to an opposing second face of the interposer 904.

The interposer 904 may further include embedded devices 914, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 904. The package-on-interposer structure 936 may take the form of any of the package-on-interposer structures known in the art.

The integrated circuit device assembly 900 may include an integrated circuit component 924 coupled to the first face 940 of the circuit board 902 by coupling components 922. The coupling components 922 may take the form of any of the embodiments discussed above with reference to the coupling components 916, and the integrated circuit component 924 may take the form of any of the embodiments discussed above with reference to the integrated circuit component 920.

The integrated circuit device assembly 900 illustrated in FIG. 9 includes a package-on-package structure 934 coupled to the second face 942 of the circuit board 902 by coupling components 928. The package-on-package structure 934 may include an integrated circuit component 926 and an integrated circuit component 932 coupled together by coupling components 930 such that the integrated circuit component 926 is disposed between the circuit board 902 and the integrated circuit component 932. The coupling components 928 and 930 may take the form of any of the embodiments of the coupling components 916 discussed above, and the integrated circuit components 926 and 932 may take the form of any of the embodiments of the integrated circuit component 920 discussed above. The package-on-package structure 934 may be configured in accordance with any of the package-on-package structures known in the art.

FIG. 10 is a block diagram of an example electrical device 1000 that may include one or more of the microelectronic assemblies or structures disclosed herein. For example, any suitable ones of the components of the electrical device 1000 may include one or more of the integrated circuit device assemblies 900, integrated circuit components 920, integrated circuit devices 500, or integrated circuit dies 402 disclosed herein, and may be arranged in any of the microelectronic assemblies or structures disclosed herein. A number of components are illustrated in FIG. 10 as included in the electrical device 1000, but any one or more of these components may be omitted or duplicated, as suitable for the application. In some embodiments, some or all of the components included in the electrical device 1000 may be attached to one or more motherboards mainboards, or system boards. In some embodiments, one or more of these components are fabricated onto a single system-on-a-chip (SoC) die.

Additionally, in various embodiments, the electrical device 1000 may not include one or more of the components illustrated in FIG. 10, but the electrical device 1000 may include interface circuitry for coupling to the one or more components. For example, the electrical device 1000 may not include a display device 1006, but may include display device interface circuitry (e.g., a connector and driver circuitry) to which a display device 1006 may be coupled. In another set of examples, the electrical device 1000 may not include an audio input device 1024 or an audio output device 1008, but may include audio input or output device interface circuitry (e.g., connectors and supporting circuitry) to which an audio input device 1024 or audio output device 1008 may be coupled.

The electrical device 1000 may include one or more processor units 1002 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1002 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1000 may include a memory 1004, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1004 may include memory that is located on the same integrated circuit die as the processor unit 1002. This memory may be used as cache memory (e.g., Level 1 (L1), Level 2 (L2), Level 3 (L3), Level 4 (L4), Last Level Cache (LLC)) and may include embedded dynamic random-access memory (eDRAM) or spin transfer torque magnetic random-access memory (STT-MRAM).

In some embodiments, the electrical device 1000 can comprise one or more processor units 1002 that are heterogeneous or asymmetric to another processor unit 1002 in the electrical device 1000. There can be a variety of differences between the processing units 1002 in a system in terms of a spectrum of metrics of merit including architectural, microarchitectural, thermal, power consumption characteristics, and the like. These differences can effectively manifest themselves as asymmetry and heterogeneity among the processor units 1002 in the electrical device 1000.

In some embodiments, the electrical device 1000 may include a communication component 1012 (e.g., one or more communication components). For example, the communication component 1012 can manage wireless communications for the transfer of data to and from the electrical device 1000. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1012 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1012 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1012 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1012 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1012 may operate in accordance with other wireless protocols in other embodiments. The electrical device 1000 may include an antenna 1022 to facilitate wireless communications and/or to receive other wireless communications (such as AM or FM radio transmissions).

In some embodiments, the communication component 1012 may manage wired communications, such as electrical, optical, or any other suitable communication protocols (e.g., IEEE 802.3 Ethernet standards). As noted above, the communication component 1012 may include multiple communication components. For instance, a first communication component 1012 may be dedicated to shorter-range wireless communications such as Wi-Fi or Bluetooth, and a second communication component 1012 may be dedicated to longer-range wireless communications such as global positioning system (GPS), EDGE, GPRS, CDMA, WiMAX, LTE, EV-DO, or others. In some embodiments, a first communication component 1012 may be dedicated to wireless communications, and a second communication component 1012 may be dedicated to wired communications.

The electrical device 1000 may include battery/power circuitry 1014. The battery/power circuitry 1014 may include one or more energy storage devices (e.g., batteries or capacitors) and/or circuitry for coupling components of the electrical device 1000 to an energy source separate from the electrical device 1000 (e.g., AC line power).

The electrical device 1000 may include a display device 1006 (or corresponding interface circuitry, as discussed above). The display device 1006 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1000 may include an audio output device 1008 (or corresponding interface circuitry, as discussed above). The audio output device 1008 may include any embedded or wired or wirelessly connected external device that generates an audible indicator, such as speakers, headsets, or earbuds.

The electrical device 1000 may include an audio input device 1024 (or corresponding interface circuitry, as discussed above). The audio input device 1024 may include any embedded or wired or wirelessly connected device that generates a signal representative of a sound, such as microphones, microphone arrays, or digital instruments (e.g., instruments having a musical instrument digital interface (MIDI) output). The electrical device 1000 may include a Global Navigation Satellite System (GNSS) device 1018 (or corresponding interface circuitry, as discussed above), such as a Global Positioning System (GPS) device. The GNSS device 1018 may be in communication with a satellite-based system and may determine a geolocation of the electrical device 1000 based on information received from one or more GNSS satellites, as known in the art.

The electrical device 1000 may include another output device 1010 (or corresponding interface circuitry, as discussed above). Examples of the other output device 1010 may include an audio codec, a video codec, a printer, a wired or wireless transmitter for providing information to other devices, or an additional storage device.

The electrical device 1000 may include another input device 1020 (or corresponding interface circuitry, as discussed above). Examples of the other input device 1020 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1000 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1000 may be any other electronic device that processes data. In some embodiments, the electrical device 1000 may comprise multiple discrete physical components. Given the range of devices that the electrical device 1000 can be manifested as in various embodiments, in some embodiments, the electrical device 1000 can be referred to as a computing device or a computing system.

As used in this application and the claims, a list of items joined by the term “and/or” can mean any combination of the listed items. For example, the phrase “A, B and/or C” can mean A; B; C; A and B; A and C; B and C; or A, B and C. As used in this application and the claims, a list of items joined by the term “at least one of” can mean any combination of the listed terms. For example, the phrase “at least one of A, B or C” can mean A; B; C; A and B; A and C; B and C; or A, B, and C. Moreover, as used in this application and the claims, a list of items joined by the term “one or more of” can mean any combination of the listed terms. For example, the phrase “one or more of A, B and C” can mean A; B; C; A and B; A and C; B and C; or A, B, and C. Furthermore, as used in this application and the claims, a list of items joined by the term “one of” can mean any one of the listed items. For example, the phrase “one of A, B, and C” can mean A, B, or C.

As used in this application and the claims, the phrase “individual of” or “respective of” following by a list of items recited or stated as having a trait, feature, etc. means that all of the items in the list possess the stated or recited trait, feature, etc. For example, the phrase “individual of A, B, or C, comprise a sidewall” or “respective of A, B, or C, comprise a sidewall” means that A comprises a sidewall, B comprises sidewall, and C comprises a sidewall.

The disclosed methods, apparatuses, and systems are not to be construed as limiting in any way. Instead, the present disclosure is directed toward all novel and nonobvious features and aspects of the various disclosed embodiments, alone and in various combinations and subcombinations with one another. The disclosed methods, apparatuses, and systems are not limited to any specific aspect or feature or combination thereof, nor do the disclosed embodiments require that any one or more specific advantages be present or problems be solved.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

Although the operations of some of the disclosed methods are described in a particular, sequential order for convenient presentation, it is to be understood that this manner of description encompasses rearrangement, unless a particular ordering is required by specific language set forth herein. For example, operations described sequentially may in some cases be rearranged or performed concurrently. Moreover, for the sake of simplicity, the attached figures may not show the various ways in which the disclosed methods can be used in conjunction with other methods.

The following examples pertain to additional embodiments of technologies disclosed herein.

Example 1 is an apparatus comprising: a first integrated circuit die comprising a first transistor region, a first layer comprising metal, a second layer comprising metal, wherein the first transistor region is positioned between the first layer and the second layer; wherein a first surface of the first integrated circuit die is opposite a second surface of the first integrated circuit die, wherein the first surface of the first integrated circuit die comprises a first conductive contact; a second integrated circuit die positioned laterally to the first integrated circuit die, the second integrated circuit die comprising a second transistor region, a third layer comprising metal, and a fourth layer comprising metal, wherein the second transistor region is positioned between the third layer and the fourth layer, wherein a first surface of the second integrated circuit die is opposite to a second surface of the second integrated circuit die, wherein the first transistor region and the second transistor region each comprise a plurality of transistors; a redistribution layer region located on the first surface of the first integrated circuit die and the first surface of the second integrated circuit die, the redistribution layer region comprising a fifth layer comprising metal and a dielectric layer; and a third integrated circuit die at least partially vertically overlapping with the first integrated circuit die, wherein a first surface of the third integrated circuit die comprises a second conductive contact attached to the first conductive contact.

Example 2 comprises the apparatus of Example 1, wherein the apparatus is an integrated circuit component, a volume extending from the first surface of the first integrated circuit die and the first surface of the second integrated circuit die in a direction away from the first transistor region toward an outer surface of the integrated circuit component does not comprise an embedded bridge.

Example 3 comprises the apparatus of Example 1, wherein redistribution layer region does not comprise an embedded bridge.

Example 4 comprises the apparatus of Example 1, wherein redistribution layer region does not comprise an embedded structure comprising metal lines.

Example 5 comprises the apparatus of any one of Examples 1-4, wherein the third integrated circuit die and the first integrated circuit die are instances of different integrated circuit die designs.

Example 6 comprises the apparatus of any one of Examples 1-5, wherein the metal of the first layer, the second layer, the third layer, and the fourth layer comprises copper, aluminum, tungsten, nickel, or ruthenium.

Example 7 comprises the apparatus of any one of Examples 1-6, wherein the first conductive contact, the second conductive contact comprise copper, aluminum, gold, nickel, titanium, or tungsten.

Example 8 comprises the apparatus of any one of Examples 1-7, wherein the metal of the fifth layer comprises copper, aluminum, tungsten, nickel, or ruthenium.

Example 9 comprises the apparatus of any one of Examples 1-8, wherein the third integrated circuit die comprises a through-silicon via extending from the first surface of the third integrated circuit die through at least a portion of the third integrated circuit die.

Example 10 comprises the apparatus of Example 9, wherein the through-silicon via comprises copper, tungsten, aluminum, or tantalum.

Example 11 comprises the apparatus of any one of Examples 1-10, further comprising a fourth integrated circuit die positioned laterally to the third integrated circuit die and at least partially vertically overlapping with the second integrated circuit die, wherein a first surface of the fourth integrated circuit die comprises a third conductive contact attached to a fourth conductive contact located on the second surface of the second integrated circuit die.

Example 12 comprises the apparatus of Example 11, further comprising: a dielectric region positioned between the third integrated circuit die and the fourth integrated circuit die; and a through-dielectric via extending through the dielectric region.

Example 13 comprises the apparatus of Example 12, wherein the through-dielectric via comprises copper, tungsten, aluminum, or tantalum.

Example 14 comprises the apparatus of Example 12, wherein the dielectric region comprises: silicon and oxygen; silicon and nitrogen; or silicon, nitrogen, or carbon.

Example 15 comprises the apparatus of Example 12, wherein the through-dielectric via is attached to a fifth conductive contact located on the second surface of the first integrated circuit die.

Example 16 comprises the apparatus of Example 12, wherein the dielectric region is a first dielectric region, the apparatus further comprising: a second dielectric region positioned between the first integrated circuit die and the second integrated circuit die; and a second through-dielectric via extending through the second dielectric region and attached to first through-dielectric via.

Example 17 comprises the apparatus of Example 16, wherein the second dielectric region comprises: silicon and oxygen; silicon and nitrogen; or silicon, nitrogen, or carbon.

Example 18 comprises the apparatus of Example 11, further comprising a dielectric region positioned between the third integrated circuit die and the fourth integrated circuit die, the dielectric region not comprising an embedded bridge.

Example 19 comprises the apparatus of Example 11, further comprising a dielectric region positioned between the third integrated circuit die and the fourth integrated circuit die, wherein the dielectric region does not comprise an embedded structure comprising metal lines.

Example 20 comprises the apparatus of any one of Examples 1-19, wherein the plurality of transistors comprises a field effect transistor.

Example 21 comprises the apparatus of Example 20, wherein the field effect transistor (FET) comprises a planar FET transistor, a FinFET transistor, a nanoribbon FET, a forksheet FET, or a complementary FET (CFET).

Example 22 comprises the apparatus of any one of Examples 1-21, wherein the first transistor region comprises silicon.

Example 23 comprises the apparatus of any one of Examples 1-22, wherein the dielectric layer of the redistribution layer region comprises: silicon and oxygen; silicon and nitrogen; or silicon, nitrogen, or carbon.

Example 24 comprises the apparatus of any one of Examples 1-23, wherein the redistribution layer region comprises a via stack comprising one or more vias vertically stacked with one or more metal lines, the via stack extending at least partially through redistribution layer region.

Example 25 comprises the apparatus of any one of Examples 1-24, wherein the apparatus comprises an integrated circuit component comprising the first integrated circuit die, the second integrated circuit die, the third integrated circuit die, and the redistribution layer region.

Example 26 comprises the apparatus of Example 25, wherein the apparatus further comprises a printed circuit board, the integrated circuit component attached to the printed circuit board.

Example 27 comprises the apparatus of Example 26, further comprising one or more second integrated circuit components attached to the printed circuit board.

Example 28 is a method comprising: attaching a first integrated circuit die to a surface of a carrier wafer, the first integrated circuit die comprising a first transistor region, a first layer comprising metal, and a second layer comprising metal, wherein the first transistor region is positioned between the first layer and the second layer; attaching a second integrated circuit die to the surface of the carrier wafer, the second integrated circuit die comprising a second transistor region, a third layer comprising metal, and a fourth layer comprising metal, wherein the second transistor region is positioned between the third layer and the fourth layer; forming a dielectric layer on the surface of the carrier wafer, a region of the dielectric layer positioned between the first integrated circuit die and the second integrated circuit die; forming a redistribution layer region on the first integrated circuit die, the second integrated circuit die and the region of the dielectric layer; attaching a substrate to the redistribution layer region; separating the carrier wafer from the first integrated circuit die, the second integrated circuit die, and the region of the dielectric layer; and attaching a structure to the first integrated circuit die, the region of the dielectric layer, and the second integrated circuit die, the structure comprising a third integrated circuit die, wherein attaching the structure comprising attaching a portion of the third integrated circuit die to at least a portion of the first integrated circuit die.

Example 29 comprises the method of Example 28, wherein redistribution layer region does not comprise an embedded bridge.

Example 30 comprises the method of Example 28, wherein redistribution layer region does not comprise an embedded structure comprising metal lines.

Example 31 comprises the method of any one of Examples 28-30, wherein the third integrated circuit die and the first integrated circuit die are instances of different integrated circuit die designs.

Example 32 comprises the method of any one of Examples 28-31, wherein the metal of the first layer, the second layer, the third layer, and the fourth layer comprises copper, aluminum, tungsten, nickel, or ruthenium.

Example 33 comprises the method of Example 28, wherein the region of the dielectric layer comprises: silicon and oxygen; silicon and nitrogen; or silicon, nitrogen, or carbon.

Example 34 comprises the method of any one of Examples 28-33, wherein the third integrated circuit die comprises a through-silicon via extending from a first surface of the third integrated circuit die through at least a portion of the third integrated circuit die.

Example 35 comprises the method of Example 34, wherein the through-silicon via comprises copper, tungsten, aluminum, or tantalum.

Example 36 comprises the method of any one of Examples 28-35, wherein the structure further comprises a fourth integrated circuit die, attaching the structure to the first integrated circuit die, the second integrated circuit die and the region of the dielectric layer comprising attaching the fourth integrated circuit die to at least a portion of the second integrated circuit die.

Example 37 comprises the method of Example 36, wherein the dielectric layer is a first dielectric layer, the structure further comprising: a second dielectric layer, a region of the second dielectric layer positioned between the third integrated circuit die and the fourth integrated circuit die; and a through-dielectric via extending through the region of the second dielectric layer.

Example 38 comprises the method of Example 37, wherein the through-dielectric via comprises copper, tungsten, aluminum, or tantalum.

Example 39 comprises the method of Example 37, wherein the region of the second dielectric layer comprises: silicon and oxygen; silicon and nitrogen; or silicon, nitrogen, or carbon.

Example 40 comprises the method of Example 28, wherein the through-dielectric via is attached to a conductive contact located on a surface of the first integrated circuit die.

Example 41 comprises the method of Example 28, wherein the region of the dielectric layer is a first dielectric region, the structure further comprising: a second dielectric region positioned between the first integrated circuit die and the second integrated circuit die; and a second through-dielectric via extending through the second dielectric region and attached to first through-dielectric via.

Example 42 comprises the method of Example 37, wherein the region of the dielectric layer is a first dielectric region, the structure further comprising a second dielectric region positioned between the first integrated circuit die and the second integrated circuit die further comprising a second dielectric region positioned between the third integrated circuit die and the fourth integrated circuit die, the second dielectric region not comprising an embedded bridge.

Example 43 comprises the method of Example 37, wherein the region of the dielectric layer is a first dielectric region, the structure further comprising a second dielectric region positioned between the first integrated circuit die and the second integrated circuit die further comprising a second dielectric region positioned between the third integrated circuit die and the fourth integrated circuit die, wherein the second dielectric region does not comprise an embedded structure comprising metal lines.

Example 44 comprises the method of any one of Examples 28-43, wherein the first transistor region and the second transistor region each comprise a field effect transistor.

Example 45 comprises the method of any one of Examples 28-44, wherein the dielectric layer of the redistribution layer region comprises: silicon and oxygen; silicon and nitrogen; or silicon, nitrogen, or carbon.

Example 46 is an apparatus comprising: a first integrated circuit die comprising: a first transistor; a first surface of the first integrated circuit die; and a second surface of the first integrated circuit die that is opposite to the first surface of the first integrated circuit die, wherein the first surface of the first integrated circuit die comprises a first conductive contact and the second surface of the first integrated circuit die comprises a second conductive contact; a second integrated circuit die positioned laterally to the first integrated circuit die, the second integrated circuit die comprising: a second transistor; a first surface of the second integrated circuit die; and a second surface of the second integrated circuit die that is opposite to the first surface of the second integrated circuit die, wherein the first surface of the second integrated circuit die comprises a third conductive contact and the first surface of the first integrated circuit die and the first surface of the second integrated circuit die are substantially coplanar; a first layer comprising metal, the first layer conductively coupled to the first conductive contact; a second layer comprising metal, the second layer conductively coupled to the second conductive contact; and a third integrated circuit die positioned vertically with the first integrated circuit die, wherein a surface of the third integrated circuit die comprises a fourth conductive contact attached to the second conductive contact.

Example 47 comprises the apparatus of Example 46, wherein the apparatus is an integrated circuit component, a volume extending from the first surface of the first integrated circuit die and the first surface of the second integrated circuit die in a direction away from the first transistor toward an outer surface of the integrated circuit component does not comprise an embedded bridge.

Example 48 comprises the apparatus of Example 46, wherein the first layer and the second layer are the same layer.

Example 49 comprises the apparatus of Example 46, wherein the first layer and the second layer are located in a redistribution layer region.

Example 50 comprises the apparatus of any one of Examples 46-49, wherein the third integrated circuit die and the first integrated circuit die are instances of different integrated circuit die designs.

Example 51 comprises the apparatus of any one of Examples 46-50, wherein the first integrated circuit die comprises a third layer comprising metal, the second integrated circuit die comprises a fourth layer comprising metal, the metal of the third layer and the fourth layer comprising copper, aluminum, tungsten, nickel, or ruthenium.

Example 52 comprises the apparatus of any one of Examples 46-51, wherein the first conductive contact and the second conductive contact comprise copper, aluminum, gold, nickel, titanium, or tungsten.

Example 53 comprises the apparatus of any one of Examples 46-51, wherein the fourth conductive contact comprises copper, aluminum, gold, nickel, titanium, or tungsten.

Example 54 comprises the apparatus of any one of Examples 46-53, wherein the metal of the first layer and the second layer comprises copper, aluminum, tungsten, nickel, or ruthenium.

Example 55 comprises the apparatus of any one of Examples 46-54, further comprising a fourth integrated circuit die positioned laterally to the third integrated circuit die and vertically to the second integrated circuit die, wherein a first surface of the fourth integrated circuit die comprises a fifth conductive contact attached to a sixth conductive contact located on the second surface of the second integrated circuit die.

Example 56 comprises the apparatus of Example 55, further comprising: a dielectric region positioned between the third integrated circuit die and the fourth integrated circuit die; and a through-dielectric via extending through the dielectric region.

Example 57 comprises the apparatus of Example 56, wherein the through-dielectric via comprises copper, tungsten, aluminum, or tantalum.

Example 58 comprises the apparatus of Example 56, wherein the dielectric region comprises: silicon and oxygen; silicon and nitrogen; or silicon, nitrogen, or carbon.

Example 59 comprises the apparatus of Example 56, wherein the through-dielectric via is attached to a seventh conductive contact located on the second surface of the first integrated circuit die.

Example 60 comprises the apparatus of Example 56, wherein the dielectric region is a first dielectric region, the apparatus further comprising: a second dielectric region positioned between the first integrated circuit die and the second integrated circuit die; and a second through-dielectric via extending through the second dielectric region and attached to first through-dielectric via.

Example 61 comprises the apparatus of Example 60 wherein the second dielectric region comprises: silicon and oxygen; silicon and nitrogen; or silicon, nitrogen, or carbon.

Example 62 comprises the apparatus of Example 55, further comprising a dielectric region positioned between the third integrated circuit die and the fourth integrated circuit die, the dielectric region not comprising an embedded bridge.

Example 63 comprises the apparatus of any one of Examples 48-62, wherein the apparatus comprises an integrated circuit component comprising the first integrated circuit die, the second integrated circuit die, and the third integrated circuit die.

Example 64 comprises the apparatus of Example 63, wherein the apparatus further comprises a printed circuit board, the integrated circuit component attached to the printed circuit board.

Example 65 comprises the apparatus of Example 64, further comprising one or more second integrated circuit components attached to the printed circuit board.

1. An apparatus comprising:
a first integrated circuit die comprising a first transistor region, a first layer comprising metal, a second layer comprising metal, wherein the first transistor region is positioned between the first layer and the second layer; wherein a first surface of the first integrated circuit die is opposite a second surface of the first integrated circuit die, wherein the first surface of the first integrated circuit die comprises a first conductive contact;
a second integrated circuit die positioned laterally to the first integrated circuit die, the second integrated circuit die comprising a second transistor region, a third layer comprising metal, and a fourth layer comprising metal, wherein the second transistor region is positioned between the third layer and the fourth layer, wherein a first surface of the second integrated circuit die is opposite to a second surface of the second integrated circuit die, wherein the first transistor region and the second transistor region each comprise a plurality of transistors;
a redistribution layer region located on the first surface of the first integrated circuit die and the first surface of the second integrated circuit die, the redistribution layer region comprising a fifth layer comprising metal and a dielectric layer; and
a third integrated circuit die at least partially vertically overlapping with the first integrated circuit die, wherein a first surface of the third integrated circuit die comprises a second conductive contact attached to the first conductive contact.

2. The apparatus of claim 1, wherein the apparatus is an integrated circuit component, a volume extending from the first surface of the first integrated circuit die and the first surface of the second integrated circuit die in a direction away from the first transistor region toward an outer surface of the integrated circuit component does not comprise an embedded bridge.

3. The apparatus of claim 1, wherein redistribution layer region does not comprise an embedded bridge.

4. The apparatus of claim 1, wherein redistribution layer region does not comprise an embedded structure comprising metal lines.

5. The apparatus of claim 1, further comprising a fourth integrated circuit die positioned laterally to the third integrated circuit die and at least partially vertically overlapping with the second integrated circuit die, wherein a first surface of the fourth integrated circuit die comprises a third conductive contact attached to a fourth conductive contact located on the second surface of the second integrated circuit die.

6. The apparatus of claim 5, further comprising:
a dielectric region positioned between the third integrated circuit die and the fourth integrated circuit die; and
a through-dielectric via extending through the dielectric region.

7. The apparatus of claim 6, wherein the dielectric region is a first dielectric region, the apparatus further comprising:
a second dielectric region positioned between the first integrated circuit die and the second integrated circuit die; and
a second through-dielectric via extending through the second dielectric region and attached to first through-dielectric via.

8. The apparatus of claim 5, further comprising a dielectric region positioned between the third integrated circuit die and the fourth integrated circuit die, the dielectric region not comprising an embedded bridge.

9. The apparatus of claim 5, further comprising a dielectric region positioned between the third integrated circuit die and the fourth integrated circuit die, wherein the dielectric region does not comprise an embedded structure comprising metal lines.

10. The apparatus of claim 1, wherein the apparatus comprises an integrated circuit component comprising the first integrated circuit die, the second integrated circuit die, the third integrated circuit die, and the redistribution layer region.

11. The apparatus of claim 10, wherein the apparatus further comprises a printed circuit board, the integrated circuit component attached to the printed circuit board.

12. A method comprising:
attaching a first integrated circuit die to a surface of a carrier wafer, the first integrated circuit die comprising a first transistor region, a first layer comprising metal, and a second layer comprising metal, wherein the first transistor region is positioned between the first layer and the second layer;
attaching a second integrated circuit die to the surface of the carrier wafer, the second integrated circuit die comprising a second transistor region, a third layer comprising metal, and a fourth layer comprising metal, wherein the second transistor region is positioned between the third layer and the fourth layer;
forming a dielectric layer on the surface of the carrier wafer, a region of the dielectric layer positioned between the first integrated circuit die and the second integrated circuit die;
forming a redistribution layer region on the first integrated circuit die, the second integrated circuit die and the region of the dielectric layer;
attaching a substrate to the redistribution layer region;
separating the carrier wafer from the first integrated circuit die, the second integrated circuit die, and the region of the dielectric layer; and
attaching a structure to the first integrated circuit die, the region of the dielectric layer, and the second integrated circuit die, the structure comprising a third integrated circuit die, wherein attaching the structure comprising attaching a portion of the third integrated circuit die to at least a portion of the first integrated circuit die.

13. The method of claim 12, wherein redistribution layer region does not comprise an embedded bridge.

14. The method of claim 12, wherein redistribution layer region does not comprise an embedded structure comprising metal lines.

15. The method of claim 12, wherein the structure further comprises a fourth integrated circuit die, attaching the structure to the first integrated circuit die, the second integrated circuit die and the region of the dielectric layer comprising attaching the fourth integrated circuit die to at least a portion of the second integrated circuit die, wherein the region of the dielectric layer is a first dielectric region, the structure further comprising a second dielectric region positioned between the first integrated circuit die and the second integrated circuit die further comprising a second dielectric region positioned between the third integrated circuit die and the fourth integrated circuit die, the second dielectric region not comprising an embedded bridge.

16. The method of claim 12, wherein the structure further comprises a fourth integrated circuit die, attaching the structure to the first integrated circuit die, the second integrated circuit die and the region of the dielectric layer comprising attaching the fourth integrated circuit die to at least a portion of the second integrated circuit die, wherein the region of the dielectric layer is a first dielectric region, the structure further comprising a second dielectric region positioned between the first integrated circuit die and the second integrated circuit die further comprising a second dielectric region positioned between the third integrated circuit die and the fourth integrated circuit die, wherein the second dielectric region does not comprise an embedded structure comprising metal lines.

17. An apparatus comprising:
a first integrated circuit die comprising:
a first transistor;
a first surface of the first integrated circuit die; and
a second surface of the first integrated circuit die that is opposite to the first surface of the first integrated circuit die, wherein the first surface of the first integrated circuit die comprises a first conductive contact and the second surface of the first integrated circuit die comprises a second conductive contact;
a second integrated circuit die positioned laterally to the first integrated circuit die, the second integrated circuit die comprising:
a second transistor;
a first surface of the second integrated circuit die; and
and a second surface of the second integrated circuit die that is opposite to the first surface of the second integrated circuit die, wherein the first surface of the second integrated circuit die comprises a third conductive contact and the first surface of the first integrated circuit die and the first surface of the second integrated circuit die are substantially coplanar;
a first layer comprising metal, the first layer conductively coupled to the first conductive contact;
a second layer comprising metal, the second layer conductively coupled to the second conductive contact; and
a third integrated circuit die positioned vertically with the first integrated circuit die, wherein a surface of the third integrated circuit die comprises a fourth conductive contact attached to the second conductive contact.

18. The apparatus of claim 17, wherein the apparatus is an integrated circuit component, a volume extending from the first surface of the first integrated circuit die and the first surface of the second integrated circuit die in a direction away from the first transistor toward an outer surface of the integrated circuit component does not comprise an embedded bridge.

19. The apparatus of claim 17, further comprising a fourth integrated circuit die positioned laterally to the third integrated circuit die and vertically to the second integrated circuit die, wherein a first surface of the fourth integrated circuit die comprises a fifth conductive contact attached to a sixth conductive contact located on the second surface of the second integrated circuit die.

20. The apparatus of claim 19, further comprising a dielectric region positioned between the third integrated circuit die and the fourth integrated circuit die, the dielectric region not comprising an embedded bridge.
